(19) United States
(12) Patent Application Publication
(10) Pub. No.: US 2015/0171114 A1
(43) Pub. Date: Jun. 18, 2015

(54) THIN FILM TRANSISTOR AND DISPLAY DEVICE USING THE SAME

(71) Applicant: Samsung Display Co., Ltd., Yongin-City (KR)

(72) Inventors: Seung-Hwan CHO, Suwon-si (KR); Su-Hyoung Kang, Bucheon-si (KR); Yoon Ho Khang, Yongin-si (KR); Young Ki Shin, Hwaseong-si (KR); Myoung Geun Cha, Seoul (KR)

(73) Assignee: Samsung Display Co., Ltd., Yongin-City (KR)

(21) Appl. No.: 14/279,204

(22) Filed: May 15, 2014

(30) Foreign Application Priority Data
Dec. 17, 2013 (KR) 10-2013-0157118

(51) Int. Cl. H01L 27/12; H01L 29/786

(52) U.S. Cl. CPC H01L 27/1225; H01L 29/78648

(57) ABSTRACT

A thin film transistor and a display device having the thin film transistor capable of reducing the voltage between the source and drain electrodes of the thin film transistor are disclosed. One inventive aspect includes a gate electrode, a semiconductor pattern, a source electrode and a drain electrode. The source and drain electrodes are formed on the semiconductor pattern and spaced apart from each other. At least one of the source electrode and the drain electrode does not overlap the gate electrode.

### CROSS-REFERENCE TO RELATED APPLICATIONS

This application claims priority to and the benefit of Korean Patent Application No. 10-2013-0157118 filed in the Korean Intellectual Property Office on Dec. 17, 2013, the entire contents of which are incorporated herein by reference.

### BACKGROUND

1. Field

The described technology generally relates to a thin film transistor and a display device using the same capable of reducing the voltage between the source and drain electrodes of the thin film transistor.

2. Description of the Related Technology

A liquid crystal display (LCD) is the type of flat panel display which has been most widely used to so far. An LCD device typically includes two sheets of the display panel and a liquid crystal layer interposed therebetween. The field generating electrodes, such as a pixel electrode and a common electrode, are formed on the display panels. The LCD displays an image by applying a voltage to the field generating electrode to generate an electric field in the liquid crystal layer, determining an orientation of liquid crystal molecules of the liquid crystal layer based on the generated electric field, and controlling a polarization of incident light. Other technologies for display include an organic light emitting diode (OLED) display, a plasma display device, an electrophoretic display, and the like, in addition to the LCD.

The display device includes a plurality of pixels and a plurality of driving units which are a unit displaying an image. The driving unit includes a data driver and a gate driver. The data driver applies a data voltage to the pixel and the gate driver applies a gate signal controlling a transfer of the data voltage. The related art has mainly used a method of mounting the gate driver and the data driver on a printed circuit board (PCB) in a chip connected to the display panel or directly mounting the driving unit chip on the display panel. Recently, however, in the case of the gate driver which does not require high mobility of a thin film transistor channel, a structure in which the gate driver is not formed as a separate chip but is integrated in the display panel has been developed.

Because the gate driver integrated in the display panel need not have a separate gate driving chip, the manufacturing cost can be reduced. Further, the gate driver can be configured as a thin film transistor which includes an oxide semiconductor using a metal oxide which is inexpensive and has high uniformity.

The gate driver generally includes a plurality of oxide semiconductor thin film transistors. In some of the oxide semiconductor thin film transistors, a high voltage is applied between a source electrode and a drain electrode (Vds) or between a gate electrode and the source electrode (Vgs). As a result, a high electric field is formed and a hot carrier is generated, such that problems, such as the occurrence of charge trapping, may occur.

The above information disclosed in this Background section is only for enhancement of understanding of the background of the invention and therefore it may contain information that does not form the prior art that is already known in this country to a person of ordinary skill in the art.

### SUMMARY OF CERTAIN INVENTIVE ASPECTS

One aspect of the disclosed technology provides a thin film transistor capable of lowering a voltage between a source electrode and a drain electrode.

Another aspect provides a thin film transistor for a gate driver of a display device, the thin film transistor including: a gate electrode, a semiconductor pattern formed on the gate electrode and made of an oxide semiconductor material, and a source electrode and a drain electrode formed on the semiconductor pattern, while being spaced apart from each other, wherein at least one of the source electrode and the drain electrode is spaced apart from the gate electrode.

The gate driver can include a plurality of stages which are connected to each other in a cascade form, an n-th (n is a natural number) stage of the stages can include: a pull-up unit outputting a high voltage of a clock signal as a high voltage of an n-th gate signal in response to a signal of a first contact, a buffer unit including a control terminal and an input terminal which are connected to a first input terminal receiving an n−1-th carry signal and an output terminal which is connected to the first contact, a pull-down unit lowering the high voltage of the n-th gate signal to a first low voltage in response to an n+1-th carry signal, a discharging unit discharging the voltage of the first contact as a second low voltage having a level lower than the first low voltage in response to the n+1-th carry signal, a carry unit outputting the high voltage of the clock signal as an n-th carry signal in response to the signal of the first contact, an inverter unit outputting a signal synchronized with the clock signal to a second contact for a period other than a period in which the n-th carry signal is output, and a first contact holding unit holding the voltage of the first contact discharged as the second low voltage at the second low voltage in response to the signal of the second contact, and the thin film transistor can be included in at least any one of the buffer unit and the first contact holding unit.

The thin film transistor can further include: a first floating electrode formed on the semiconductor pattern, in which the first floating electrode can partially overlap or can be spaced apart from the gate electrode and can be spaced apart from the source electrode and the drain electrode.

The source electrode can be spaced apart from the gate electrode and the first floating electrode can be formed between the gate electrode and the source electrode.

The thin film transistor can further include: a second floating electrode formed on the semiconductor pattern, in which the drain electrode can be spaced apart from the gate electrode and the second floating electrode can partially overlap or can be spaced apart from the gate electrode, can be spaced apart from the source electrode and the drain electrode, and can be formed between the gate electrode and the drain electrode.

The drain electrode can overlap the gate electrode.

The source electrode can be spaced apart from the gate electrode and the drain electrode can overlap the gate electrode.

The thin film transistor can further include: a second floating electrode formed on the semiconductor pattern, in which the second floating electrode can partially overlap or can be spaced apart from the gate electrode and can be spaced apart from the source electrode and the drain electrode.

The drain electrode can be spaced apart from the gate electrode and the second floating electrode can be formed between the gate electrode and the drain electrode.

The source electrode can overlap the gate electrode.

The drain electrode can be spaced apart from the gate electrode and the source electrode can overlap the gate electrode.

The thin film transistor can further include: a floating gate electrode formed on the semiconductor pattern.

The thin film transistor can further include: a first floating electrode formed on the semiconductor pattern, in which the first floating electrode can partially overlap or can be spaced apart from the gate electrode and can be spaced apart from the source electrode and the drain electrode.

The source electrode can be spaced apart from the gate electrode and the first floating electrode can be formed between the gate electrode and the source electrode.

The thin film transistor can further include: a second floating electrode formed on the semiconductor pattern, in which the drain electrode can be spaced apart from the gate electrode and the second floating electrode can partially overlap or can be spaced apart from the gate electrode, can be spaced apart from the source electrode and the drain electrode, and can be formed between the gate electrode and the drain electrode.

The drain electrode can overlap the gate electrode.

The source electrode can be spaced apart from the gate electrode and the drain electrode can overlap the gate electrode.

The floating gate electrode can overlap a central portion of the gate electrode.

The floating gate electrode can be made of the same material as the source electrode and the drain electrode and can be formed on the same layer as the source electrode and the drain electrode.

As set forth above, the thin film transistor according to the exemplary embodiments of the disclosed technology has the following effects.

According to another aspect, the offset is formed between the gate electrode and the source/drain electrode, thereby lowering the voltage between the source electrode and the drain electrode.

### BRIEF DESCRIPTION OF THE DRAWINGS

FIG. 1 is a plan view of a display device according to an exemplary embodiment of the disclosed technology.

FIG. 2 is a block diagram of a gate driver of the display device according to the exemplary embodiment of the disclosed technology.

FIG. 3 is a circuit diagram of one stage of the gate driver of the display device according to the exemplary embodiment of the disclosed technology.

FIG. 4 is a cross-sectional view of a thin film transistor according to an exemplary embodiment of the disclosed technology.

FIG. 5 is an equivalent circuit diagram of the thin film transistor according to the exemplary embodiment of the disclosed technology.

FIGS. 6A to 6D are process cross-sectional views of a method for manufacturing a thin film transistor according to another exemplary embodiment of the disclosed technology.

FIG. 7 is a cross-sectional view of the thin film transistor according to the exemplary embodiment of the disclosed technology.

FIGS. 8A to 8D are process cross-sectional views of a method for manufacturing a thin film transistor according to another exemplary embodiment of the disclosed technology.

FIG. 9 is a cross-sectional view of the thin film transistor according to another exemplary embodiment of the disclosed technology.

FIGS. 10A to 10D are process cross-sectional views of a method for manufacturing a thin film transistor according to another exemplary embodiment of the disclosed technology.

FIG. 11 is a cross-sectional view of the thin film transistor according to the exemplary embodiment of the disclosed technology.

FIGS. 12A to 12D are process cross-sectional views of a method for manufacturing a thin film transistor according to another exemplary embodiment of the disclosed technology.

FIG. 13 is a cross-sectional view of the thin film transistor according to another exemplary embodiment of the disclosed technology.

FIGS. 14A to 14D are process cross-sectional views of a method for manufacturing a thin film transistor according to another exemplary embodiment of the disclosed technology.

FIG. 15 is a cross-sectional view of the thin film transistor according to another exemplary embodiment of the disclosed technology.

FIGS. 16A to 16D are process cross-sectional views of a method for manufacturing a thin film transistor according to another exemplary embodiment of the disclosed technology.

FIG. 17 is a cross-sectional view of the thin film transistor according to another exemplary embodiment of the disclosed technology.

FIGS. 18A to 18D are process cross-sectional views of a method for manufacturing a thin film transistor according to another exemplary embodiment of the disclosed technology.

FIG. 19 is a cross-sectional view of the thin film transistor according to anther exemplary embodiment of the disclosed technology.

FIGS. 20A to 20D are process cross-sectional views of a method for manufacturing a thin film transistor according to another exemplary embodiment of the disclosed technology.

### DETAILED DESCRIPTION OF CERTAIN INVENTIVE EMBODIMENTS

Hereinafter, the disclosed technology will be described more fully hereinafter with reference to the accompanying drawings, in which exemplary embodiments of the invention are shown. As those skilled in the art would realize, the described embodiments may be modified in various different ways, all without departing from the spirit or scope of the disclosed technology.

In the drawings, the thickness of layers, films, panels, regions, etc., are exaggerated for clarity. Like reference numerals designate like elements throughout the specification. It will be understood that when an element such as a layer, film, region, or substrate is referred to as being “on” another element, it can be directly on the other element or intervening elements may also be present. In contrast, when an element is referred to as being “directly on” another element, there are no intervening elements present.

First, a display device including a thin film transistor according to an exemplary embodiment of the disclosed technology will be described below with reference to the accompanying drawings.

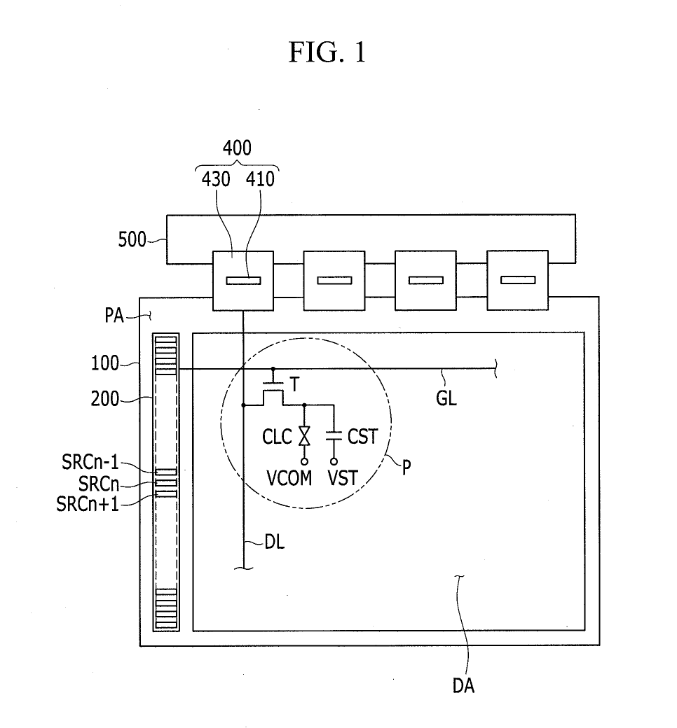

FIG. 1 is a plan view of a display device according to an exemplary embodiment of the disclosed technology.

Referring to FIG. 1, the display device includes a display panel 100, a gate driver 200, a data driver 400, and a printed circuit board (PCB) 500.

The display panel 100 includes a display area DA and a peripheral area PA surrounding the display area DA. The display area DA is provided with a gate line GL and a data line DL. The gate line GL and the data line DL intersect each other and a plurality of pixel units P. Each of the pixel units P includes a switching element T, a liquid crystal capacitor CLC, and a storage capacitor CST. The switching element T is electrically connected to a gate line GL and a data line DL. The liquid crystal capacitor CLC is electrically connected to the switching element T. The storage capacitor CST is connected to the liquid crystal capacitor CLC in parallel.

The gate driver 200 includes a shift register. The shift register sequentially outputs high-level gate signals to the gate lines GLs. The shift register includes a plurality of stages SRCn−1, SRCn, and SRCn+1 (n is a natural number). The gate driver 200 may be integrated in the peripheral area (PA) which corresponds to one end of the gate line GL. Although the exemplary embodiment of the disclosed technology describes that the gate driver 200 is integrated corresponding to the one end of the gate line GL, the gate driver 200 may also be integrated corresponding to both ends of the gate line GL.

The data driver 400 includes a source driving chip 410 and a flexible printed circuit board 430. The source driving chip 410 outputs data signals to the data line DL. The flexible printed circuit board 430 is mounted with the source driving chip 410 to electrically connect a printed circuit board 500 to the display panel 100. Although the exemplary embodiment of the disclosed technology describes that the source driving chip 410 is mounted on the flexible printed circuit board 430, but the source driving chip 410 may be directly mounted on the display panel 100 and the source driving chip 410 may also be directly integrated in the peripheral area PA of the display panel 100.

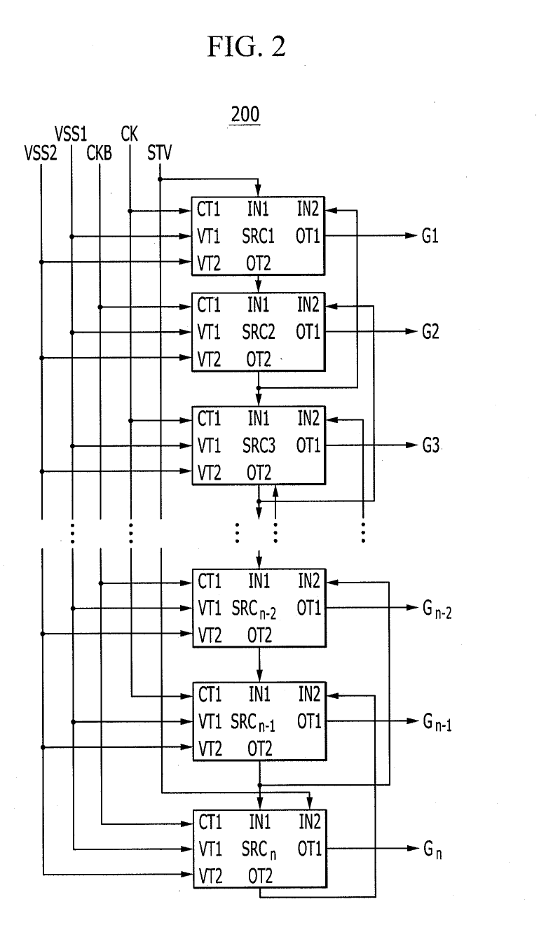

Next, the gate driver of the display device according to the exemplary embodiment of the disclosed technology will be described below with reference to FIG. 2.

FIG. 2 is a block diagram of a gate driver of the display device according to the exemplary embodiment of the disclosed technology.

The gate driver 200 of the display device according to the exemplary embodiment of the disclosed technology includes a shift register which includes first to n-th stages SRC1 to SRCn which are connected to each other in a cascade form.

The first to n-th stages SRC1 to SRCn are each connected to n gate lines to sequentially output n gate signals to the gate lines.

Each stage includes a first clock terminal CT1, a first input terminal IN1, a second input terminal IN2, a first voltage terminal VT1, a second voltage terminal VT2, a first output terminal OT1, and a second output terminal OT2.

The first clock terminal CT1 receives a clock signal CK or an inverted clock signal CKB. The inverted clock signal CKB is obtained by inverting a phase of the clock signal CK. In one exemplary implementation, the first clock terminals CT1 of odd-numbered stages SRC1, SRC3, . . . , SRCn receive the clock signal CK and the first clock terminals CT1 of even-numbered stages SRC2, SRC4, . . . , SRCn+1 receive the inverted clock signal CKB. The clock signal CK and the inverted clock signal CKB are formed of a high voltage VDD and a first low voltage VSS1.

The first input terminal IN1 receives a vertical start signal STV or an n−1-th carry signal Cr (n−1). In one exemplary implementation, the first input terminal IN1 of the first stage SRC1 receives the vertical start signal STV. The first input terminals IN1 of the second stage SRC2 to n-th stage SRCn each receive the n−1-th carry signal Cr (n−1).

The second input terminal IN2 receives an n+1 carry signal (Cr (n+1) or the vertical start signal STV. In one exemplary implementation, the second input terminals IN2 of the first stage SRC1 to the n−1 stage SRCn−1 each receive the (n+1)-th carry signal Cr (n+1). The second input terminal IN2 of the n-th stage SRCn receives the vertical start signal STV. The vertical start signal STV received by the second input terminal IN2 of the n-th stage SRCn is a vertical start signal corresponding to the next frame.

The first voltage terminal VT1 receives a first low voltage VSS1. The first low voltage VSS has a first low level. The first low level corresponds to a discharge level of the gate signal. In one exemplary implementation, the first low level is about −6V.

The second voltage terminal VT2 receives a second low voltage VSS2 which has a second low level lower than the first low level. The second low level corresponds to a discharge level of a first contact Q included in the stage. In one exemplary implementation, the second low level is about −10V.

The first output terminal OT1 is electrically connected to the corresponding gate line to output the gate signal. The first output terminals OT1 of the first stage to the n-th stage SRC1 to SRCn each output first to n-th gate signals. In one exemplary implementation, the first output terminal OT1 of the first stage SRC1 is electrically connected to the first gate line to output a first gate signal G1 and the first output terminal OT1 of the second stage SRC2 is electrically connected to the second gate line to output a second gate signal G2. The first gate signal G1 is first output and then the second gate signal G2 is output. Next, a third gate signal G3 to an n-th gate signal Gn are sequentially output.

The second output terminal OT2 outputs a carry signal Cr(n). The second output terminal OT2 of the n−1-th stage SRCn−1 is electrically connected to the first input terminal IN1 of the n-th stage SRCn. Further, the second output terminal OT2 of the n-th stage SRn is electrically connected to the second input terminal IN2 of the n−1-th stage SRCn−1.

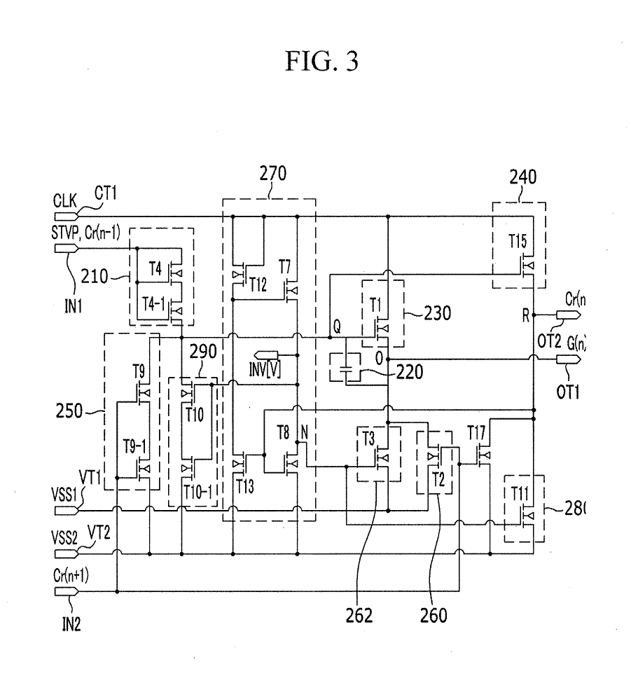

Next, one stage of the gate driver of the display device according to the exemplary embodiment of the disclosed technology will be described below with reference to FIG. 3.

FIG. 3 is a circuit diagram of one stage of the gate driver of the display device according to the exemplary embodiment of the disclosed technology.

The n-th stage SRCn of the gate driver of the display device according to the exemplary embodiment of the disclosed technology includes a buffer unit 210, a charging unit 220, a pull-up unit 230, a pull-down unit 260, an output contact holding unit 262, a carry unit 240, a third contact holding unit 280, an inverter unit 270, a discharging unit 250, a first contact holding unit 290, and the like.

The buffer unit 210 transfers the (n−1)-th carry signal Cr(n−1) to the pull-up unit 230. The buffer unit 210 includes a fourth transistor T4. The fourth transistor T4 includes a control terminal, an input terminal and an output terminal. The control terminal and input terminal of the fourth transistor T4 are connected to the first input terminal IN1. The output terminal of the fourth transistor T4 is connected to the first contact Q.

Further, the buffer unit 210 further includes a fourth additional transistor T4-1. The fourth additional transistor T4-1 includes a control terminal, an input terminal and an output terminal. The control terminal of the fourth additional transistor T4-1 is connected to the first input terminal IN1. The input terminal of the fourth additional transistor T4-1 is connected to the fourth transistor T4. The output terminal of the fourth additional transistor T4-1 is connected to the first contact Q. In this case, the output terminal of the fourth transistor T4 is connected to the input terminal of the fourth additional transistor T4-1, instead of the first contact Q.

The charging unit 220 is charged in response to the n−1-th carry signal Cr(n−1). The n−1-th carry signal Cr(n−1) is provided by the buffer unit 210. One end of the charging unit 220 is connected to the first contact Q and the other end thereof is connected to an output contact O of the gate signal. When the buffer unit 210 receives a high voltage VDD of the n−1-th carry signal Cr(n−1), the charging unit 220 charges a first voltage V1. The first voltage V1 corresponds to the high voltage VDD.

The pull-up unit 230 outputs the gate signal. The pull-up unit 230 includes a first transistor T1. The first transistor T1 includes a control terminal, an input terminal and an output terminal. The control terminal of the first transistor T1 is connected to the first contact Q. The input terminal of the first transistor T1 is connected to the first clock terminal CT1. The output terminal of the first transistor T1 is connected to the output contact O. The output contact O is connected to the first output terminal OT1.

When the first clock terminal CT1 is applied with the high voltage VDD of the clock signal CK in the state in which the control terminal of the pull-up unit 230 is applied with the first voltage V1, the pull-up unit 230 is bootstrapped. The first voltage V1 is charged by the charging unit 220. In this case, the first contact Q is connected to the control terminal of the pull-up unit 230 and boosted to a boosting voltage VBT at the first voltage V1. That is, the first contact Q first rises to the first voltage V1 and then rises to the boosting voltage VBT again.

While the control terminal of the pull-up unit 230 is applied with the boosting voltage VBT, the pull-up unit 230 outputs the high voltage VDD of the clock signal CK as the high voltage VDD of the n-th gate signal G(n). The n-th gate signal G(n) is output through the first output terminal OT1. The first output terminal OT1 is connected to the output contact O.

The pull-down unit 260 pulls-down the n-th gate signal G(n). The pull-down unit 260 may include a second transistor T2. The second transistor T2 includes a control terminal, an input terminal, and an output terminal. The control terminal is connected to the second input terminal IN2. The input terminal is connected to an output contact O. The output terminal is connected to the first voltage terminal VT1. When the second input terminal IN2 is applied with the n+1-th carry signal Cr(n+1), the pull-down unit 260 pulls-down the voltage of the output contact O to the first low voltage VSS1 applied to the first voltage terminal VT1.

The output contact holding unit 262 holds the voltage of the output contact O. The output contact holding unit 262 includes a third transistor T3. The third transistor T3 includes a control electrode, and input electrode and an output electrode. The control electrode of the third transistor T3 is connected to the second contact N. The input electrode of the third transistor T3 is connected to the output contact O. The output electrode of the third transistor T3 is connected to the first voltage terminal VT1. The output contact holding unit 262 holds the voltage of the output contact O at the first low voltage VSS1 applied to the first voltage terminal VT1 in response to the signal of the second contact N.

The pulled-down voltage of the output contact O to the first low voltage VSS1 may be more stably held by the output contact holding unit 262 and in some cases, the output contact holding unit 262 may be omitted.

The carry unit 240 outputs the carry signal Cr(n). The carry unit 240 may include a fifteenth transistor T15. The fifteenth transistor T15 includes a control terminal, an input terminal, and an output terminal. The control terminal of the fifteenth transistor T15 is connected to the first contact Q. The input terminal of the fifteenth transistor T15 is connected to the first clock terminal CT1. The output terminal of the fifteenth transistor T15 is connected to a third contact R. The third contact R is connected to the second output terminal OT2.

The carry unit 240 may further include a capacitor which connects the control terminal to the output terminal. When the first contact Q is applied with a high voltage, the carry unit 240 outputs the high voltage VDD of the clock signal CK received by the first clock terminal CT1 as the n-th carry signal Cr(n). The n-th carry signal Cr(n) is output through the second output terminal OT2. The second output terminal OT2 is connected to the third contact R.

The third contact holding unit 280 holds the voltage of the third contact R. The third contact holding unit 280 may include an eleventh transistor T11. The eleventh transistor T11 includes a control terminal, an input terminal, and an output terminal. The control terminal of the eleventh transistor T11 is connected to the second contact N. The input terminal of the eleventh transistor T11 is connected to the third contact R. The output terminal of the eleventh transistor T11 is connected to the second voltage terminal VT2. The third contact holding unit 280 holds the voltage of the third contact R at the second low voltage VSS2 in response to the signal of the second contact N.

The inverter unit 270 applies a signal having the same phase as the clock signal CK received by the first clock terminal CT1 to the second contact N for a period other than a period in which the n-th carry signal Cr(n) is output

The inverter unit 270 may include a twelfth transistor T12, a seventh transistor T7, a thirteenth transistor T13, and an eighth transistor T8.

The twelfth transistor T12 includes a control terminal and an input terminal, and an output terminal. The control terminal and input terminal of the twelfth transistor T12 are connected to the first clock terminal CT1. The output terminal of the twelfth transistor T12 is connected to an input terminal of the thirteenth transistor T13 and the seventh transistor T7.

The seventh transistor T7 includes a control terminal, an input terminal, and an output terminal. The control terminal of the seventh transistor T7 is connected to the thirteenth transistor T13. The input terminal of the seventh transistor T7 is connected to the first clock terminal CT1. The output terminal of the seventh transistor T7 is connected to the input terminal of the eighth transistor T8. The output terminal of the seventh transistor T7 is connected to the second contact N.

The thirteenth transistor T13 includes a control terminal, an input terminal, and an output terminal. The control terminal of the thirteenth transistor T13 is connected to the third contact R. The input terminal of the thirteenth transistor T13 is connected to the twelfth transistor T12. The output terminal of the thirteenth transistor T13 is connected to the second voltage terminal VT2.

The eighth transistor T8 includes a control terminal, an input terminal, and an output terminal. The control terminal of the eighth transistor T8 is connected to the third contact R. The input terminal of the eighth transistor T8 is connected to the second contact N. The output terminal of the eighth transistor T8 is connected to the second voltage terminal VT2.

The inverter unit 270 discharges the clock signal CK received by the first clock terminal CT1 at the second low voltage VSS2 applied to the second voltage terminal VT2 while the high voltage is applied to the third contact R. That is, the eight and thirteenth transistors T8 and T13 are turned on in response to the high voltage of the third contact R, such that the clock signal CK is discharged at the second low voltage VSS2. Therefore, the second contact N is held at the second low voltage VSS2 while the n-th gate signal G(n) is output. The second contact N is the output contact of the inverter unit 270

The discharging unit 250 discharges the high voltage of the first contact Q as the second low voltage VSS2 having a level lower than the first low voltage VSS1 in response to the n-th+1 carry signal Cr (n+1). The discharging unit 250 may include a ninth transistor T9. The ninth transistor T9 includes a control terminal, an input terminal, and an output terminal. The control terminal of the ninth transistor T9 is connected to the second input terminal IN2. The input terminal of the ninth transistor T9 is connected to the first contact O. The output terminal of the ninth transistor T9 is connected to the second voltage terminal VT2

Further, the discharging unit 250 further includes a ninth additional transistor T9-1. The ninth additional transistor T9-1 may include a control terminal, an input terminal, and an output terminal. The control terminal of the ninth additional transistor T9-1 is connected to the second input terminal IN2. The input terminal of the ninth additional transistor T9-1 is connected to the ninth transistor T9. The output terminal of the ninth additional transistor T9-1 is connected to the second voltage terminal VT2. In this case, the output terminal of the ninth transistor T9 is connected to the input terminal of the ninth additional transistor T9-1, instead of the second voltage terminal VT2.

When the n+1-th carry signal Cr(n+1) is applied to the second input terminal IN2, the discharging unit 250 discharges the voltage of the first contact Q as the second low voltage VSS2 is applied to the second voltage terminal VT2.

Therefore, the voltage of the first contact Q rises from the first voltage V1 to the boosting voltage VBT and then reduces to the second low voltage VSS2.

As described above, the disclosed technology describes that the output terminal of the ninth transistor T9 is connected to the second voltage terminal VT2, but is not limited thereto and the output terminal of the ninth transistor T9 may also be connected to the first voltage terminal VT1.

The first contact holding unit 290 holds the voltage of the first contact O. The first contact holding unit 290 may include a tenth transistor T10. The tenth transistor T10 includes a control terminal, an input terminal, and an output terminal. The control terminal of the tenth transistor T10 is connected to the second contact N. The input terminal of the tenth transistor T10 is connected to the first contact Q. The output terminal of the tenth transistor T10 is connected to the second voltage terminal VT2.

Further, the first contact holding unit 290 may further include a tenth additional transistor T10-1. The tenth additional transistor T10-1 includes a control terminal, an input terminal, and an output terminal. The control terminal of the tenth additional transistor T10-1 is connected to the second contact N. The input terminal of the tenth additional transistor T10-1 is connected to the tenth additional transistor T10. The output terminal of the tenth additional transistor T10-1 is connected to the second voltage terminal VT2. In this case, the output terminal of the tenth transistor T10 may be connected to the input terminal of the tenth additional transistor T10-1.

The first contact holding unit 290 holds the voltage of the first contact Q at the second low voltage VSS2 in response to the signal of the second contact N.

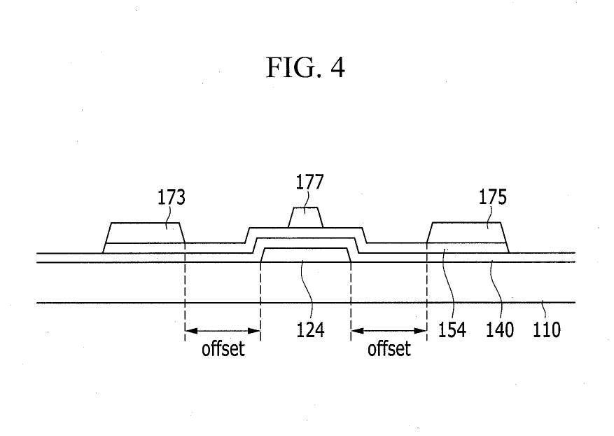

Next, a thin film transistor according to the exemplary embodiment of the disclosed technology will be described below with reference to FIG. 4. The thin film transistor according to the exemplary embodiment of the disclosed technology may be at least any one of the transistors configuring the gate driver of the display device according to the exemplary embodiment of the disclosed technology as described above. Particularly, the thin film transistor according to the exemplary embodiment of the disclosed technology may be the fourth transistor T4 or the tenth transistor T10 in which the high voltage is applied between the input terminals and the output terminals.

FIG. 4 is a cross-sectional view of the thin film transistor according to the exemplary embodiment of the disclosed technology.

The thin film transistor according to the exemplary embodiment of the disclosed technology includes a gate electrode 124. The gate electrode 124 is formed on an insulating substrate 110 made of a material such as glass and plastic.

The gate electrode 124 may be made of a low resistance metal material. Although not illustrated, the gate line connected to the gate electrode 124 may be formed and the gate signal is applied to the gate electrode 124 through the gate line.

A gate insulating layer 140 is formed on the gate electrode 124. The gate insulating layer 140 may be made of an inorganic insulating material such as silicon nitride (SiNx), silicon oxide (SiOx), and the like.

A semiconductor pattern 154 is formed on the gate insulating layer 140. The semiconductor pattern 154 is formed to overlap the gate electrode 124. The semiconductor pattern 154 may be made of an oxide semiconductor material. In one exemplary implementation, the semiconductor pattern 154 is made of one of indium gallium zinc oxide (IGZO), zinc tin oxide (ZTO), indium tin oxide (ITO), or the like.

A source electrode 173 and a drain electrode 175 are formed on the semiconductor pattern 154. The source electrode 173 and the drain electrode 175 are spaced apart from each other. The source electrode 173 and the drain electrode 175 may be made of a low resistance metal material. In one exemplary implementation, the source electrode 173 and the drain electrode 175 are made of at least any one of copper (Cu), aluminum (Al), silver (Ag), molybdenum (Mo), chromium (Cr), gold (Au), platinum (Pt), palladium (Pd), tantalum (Ta), tungsten (W), titanium (Ti), nickel (Ni), or an alloy thereof. Further, the source electrode 173 and the drain electrode 175 may be formed of a single layer or a multilayer. That is, the source electrode 173 and the drain electrode 175 may be formed of a double layer, a triple layer, and the like which are made of different materials.

The source electrode 173 and the drain electrode 175 are spaced apart from the gate electrode 124. That is, the source electrode 173 and the drain electrode 175 are formed so as not to overlap the gate electrode 124 on a plane. Therefore, the source electrode 173 and the drain electrode 175 are formed so as not to cover an upper surface of the gate electrode 124. As illustrated, an offset is formed between the gate electrode 124 and the source electrode 173. The offset is the same as the distance at which the gate electrode 124 and the source electrode 173 are spaced apart from each other. Further, as illustrated, another offset is formed between the gate electrode 124 and the drain electrode 175. The another offset is the same as the distance at which the gate electrode 124 and the drain electrode 175 are spaced apart from each other. Due to the formation of the offset, it is possible to lower a potential difference between the source electrode 173 and the drain electrode 175 by increasing a resistance between the source electrode 173 and the drain electrode 175.

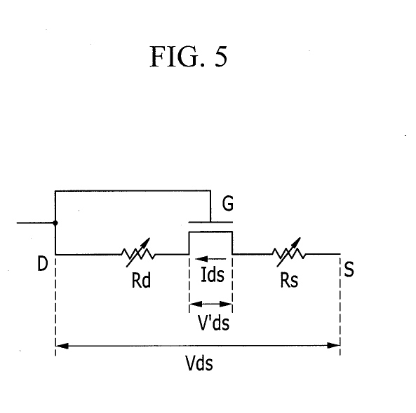

The reduction in the potential difference between the source electrode and the drain electrode depending on the formation of the offset will be described with reference to FIG. 5 and Equation 1.

FIG. 5 is an equivalent circuit diagram of the thin film transistor according to the exemplary embodiment of the disclosed technology.

A predetermined voltage Vds is applied between a source electrode S and a drain electrode D of the thin film transistor. In this case, the applied voltage Vds is a high voltage. According to the exemplary embodiment of the disclosed technology, an offset is formed between the gate electrode G and the source electrode S. As such, a first additional resistance Rs is formed. Further, an offset is formed between the gate electrode G and the drain electrode D. As such, a second additional resistance Rd is formed. As represented by Equation 1, a voltage reduction which corresponds to a size obtained by multiplying a sum of the first additional resistance Rs and the second additional resistance Rd by a current flowing between the source electrode S and the drain electrode D occurs. That is, the voltage reduction occurs in proportion to a sum of the first additional resistance Rs and the second additional resistance Rd.

V′ds=Vds−Ids(Rs+Rd) [Equation 1]

Therefore, it is possible to prevent the thin film transistor from deteriorating by reducing the voltage applied between the source electrode S and the drain electrode D.

Referring again to FIG. 4, a floating gate electrode 177 is formed on the semiconductor pattern 154. The floating gate electrode 177 is made of the same material as the source electrode 173 and the drain electrode 175. The floating gate electrode 177 is formed on the same layer as the source electrode 173 and the drain electrode 175. The floating gate electrode 177 is formed in a floated state. The floating gate electrode 177 is formed to overlap the gate electrode 124. The floating gate electrode 177 is particularly formed to overlap a central portion of the gate electrode 124. Due to the formation of the floating gate electrode 177, it is possible to relieve a lateral electric field which is present in a channel of the semiconductor pattern 154. According to the exemplary embodiment of the disclosed technology, as the source electrode 173 and the drain electrode 175 are formed to be spaced apart from the gate electrode 124, a channel length extends and the lateral electric field is generated. However, due to the formation of the floating gate electrode 177, the lateral electric field may be relieved.

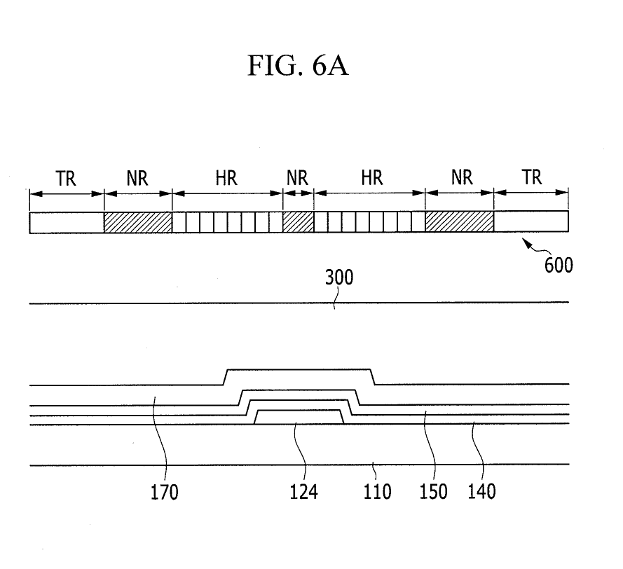

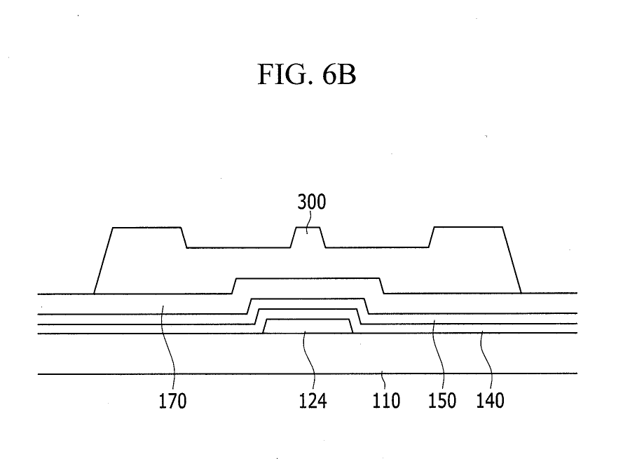

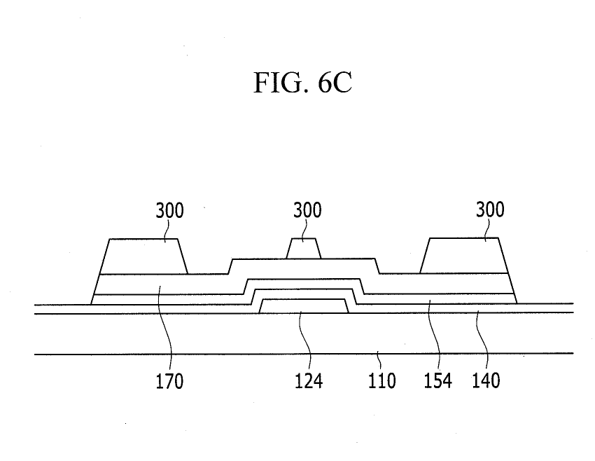

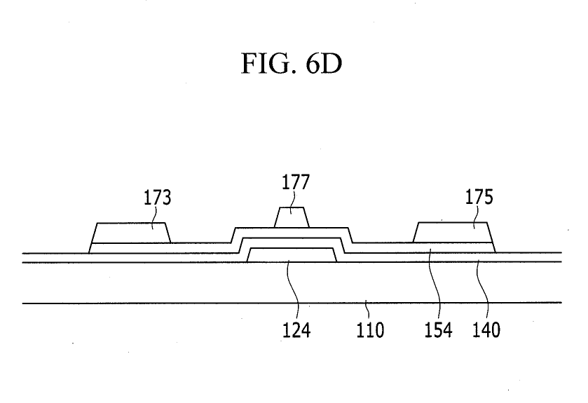

Next, a method for manufacturing a thin film transistor according to another exemplary embodiment of the disclosed technology will be described below with reference to FIGS. 6A to 6D.

FIGS. 6A to 6D are process cross-sectional views of a method for manufacturing a thin film transistor according to another exemplary embodiment of the disclosed technology.

As illustrated in FIG. 6A, the gate electrode 124 is formed on the insulating substrate 110 made of a material such as glass and plastic by using the low resistance metal material.

Next, the gate insulating layer 140 is formed on the gate electrode 124 by using an inorganic insulating material such as silicon nitride (SiNx), silicon oxide (SiOx), and the like.

Next, the semiconductor material layer 150 is formed on the gate insulating layer 140 by using the oxide semiconductor material such as indium gallium zinc oxide (IGZO), zinc tin oxide (ZTO), and/or indium tin oxide (I TO). A metal material layer 170 is formed on the semiconductor material layer 150 by using a low resistance metal material. A photosensitive material is applied on the metal material layer 170 to form a photosensitive film 300.

Next, a mask 600 is applied onto the substrate 110 and undergoes an exposure process by being irradiated with light. The mask 600 may be formed of at least one of a slit mask, a half tone mask, or the like. The mask 600 includes a transmitting part TR, a non-transmitting part NR and a half transmitting part HR. The transmitting part TR completely transmits light irradiated to the mask 600. The non-transmitting part NR does not transmit light. The half transmitting part HR transmits only a portion of light.

As illustrated in FIG. 6B, the photosensitive film 300 is developed. The photosensitive film 300 has at least two thicknesses.

A first portion of the photosensitive film 300 corresponding to the transmitting part TR of the mask 600 is removed. A second portion of the photosensitive film 300 which corresponds to the non-transmitting part NR and the half transmitting part HR of the mask 600 remains. In this case, the thickness of the third portion of the photosensitive film 300 corresponding to the non-transmitting part NR of the mask 600 remains to be larger than that of the fourth portion of the photosensitive film 300 corresponding to the half transmitting part HR of the mask 600.

As illustrated in FIG. 6C, the metal material layer 170 and the semiconductor material layer 150 are etched by using the photosensitive film 300 as the mask. After the etching process is performed, the remaining portion of the semiconductor material layer 150 becomes the semiconductor pattern 154.

Next, the photosensitive film 300 is ashed and thus the portion of the photosensitive film 300 formed at a small thickness is removed. That is, the portion of the photosensitive film 300 corresponding to the non-transmitting part HR of the mask 600 is removed. The thickness of the photosensitive film 300 corresponding to the non-transmitting part HR of the mask 600 is small.

As illustrated in FIG. 6D, the metal material layer 170 is etched by using the remaining photosensitive film 300 as the mask. After the etching process is performed, the portion of the remaining metal material layer 170 becomes the source electrode 173, the drain electrode 175, and the floating gate electrode 177.

The source electrode 173 and the drain electrode 175 are formed at both sides of the gate electrode 124, while being spaced apart from each other and the floating gate electrode 177 is formed between the source electrode 173 and the drain electrode 175. The source electrode 173 and the drain electrode 175 is spaced apart from the gate electrode 124 to form the offset. The floating gate electrode 177 is formed to overlap the gate electrode 124 and is particularly formed to overlap the central portion of the gate electrode 124.

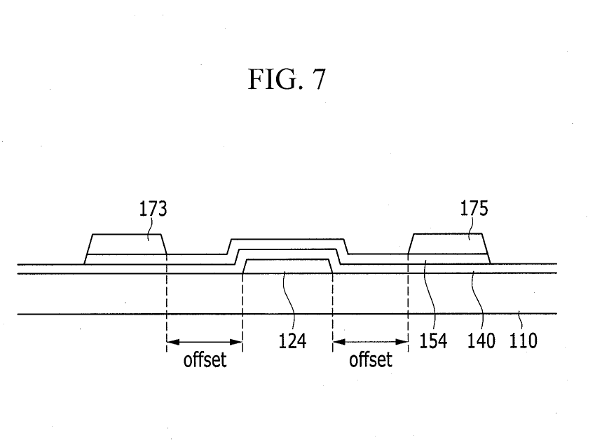

Next, the thin film transistor according to the exemplary embodiment of the disclosed technology will be described below with reference to FIG. 7.

The thin film transistor according to the exemplary embodiment of the disclosed technology illustrated in FIG. 7 is considerably the same as the thin film transistor according to the exemplary embodiment of the disclosed technology illustrated in FIG. 4 and therefore the description thereof will be omitted. The exemplary embodiment of the disclosed technology is different from the foregoing exemplary embodiments of the disclosed technology in that the floating gate electrode is omitted and will be described below in more detail.

FIG. 7 is a cross-sectional view of the thin film transistor according to the exemplary embodiment of the disclosed technology.

The thin film transistor according to the exemplary embodiment of the disclosed technology includes the gate electrode 124, the gate insulating layer 140, and the semiconductor pattern 154. The gate electrode 124 is formed on the substrate 110. The gate insulating layer 140 is formed on the gate electrode 124. The semiconductor pattern 154 is made of the oxide semiconductor and formed on the gate insulating layer 140.

The source electrode 173 and the drain electrode 175 are formed on the semiconductor pattern 154. The source electrode 173 and the drain electrode 175 are spaced apart from each other. The source electrode 173 and the drain electrode 175 are spaced apart from the gate electrode 124. That is, the source electrode 173 and the drain electrode 175 are formed so as not to overlap the gate electrode 124 to form the offset.

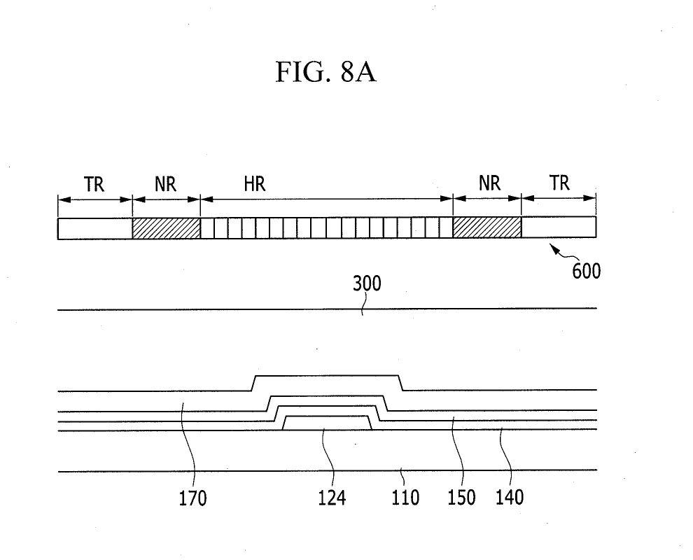

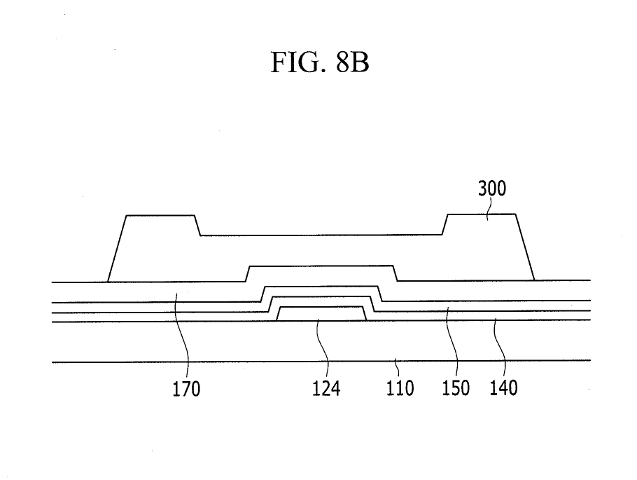

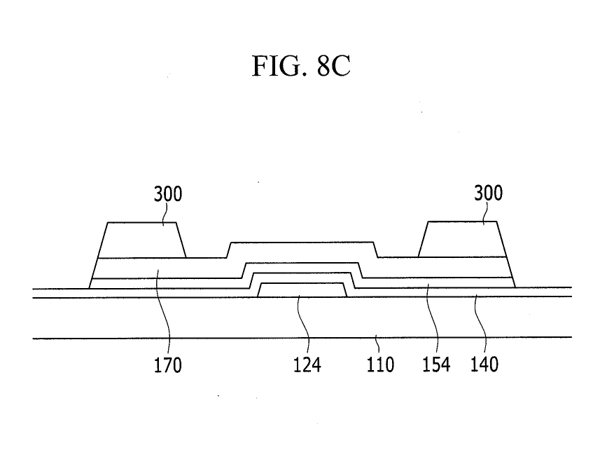

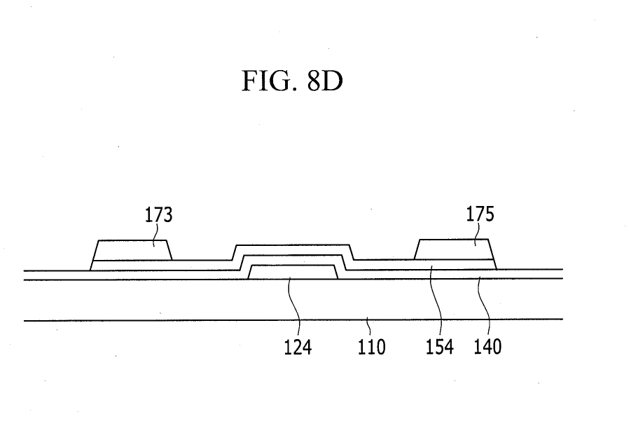

Next, a method for manufacturing a thin film transistor according to another exemplary embodiment of the disclosed technology will be described below with reference to FIGS. 8A to 8D.

FIGS. 8A to 8D are process cross-sectional views of a method for manufacturing a thin film transistor according to another exemplary embodiment of the disclosed technology.

As illustrated in FIG. 8A, the gate electrode 124 is formed on the substrate 110 and the gate insulating layer 140 is formed on the gate electrode 124. The semiconductor material layer 150 made of the oxide semiconductor material is formed on the gate insulating layer 140 and the metal material layer 170 is formed on the semiconductor material layer 150. The photosensitive film 300 is formed on the metal material layer 170 and the mask 600 is applied on the substrate 110 and undergoes the exposure process by being irradiated with light. The mask 600 includes the transmitting part TR, the non-transmitting part NR, and the half transmitting part HR.

As illustrated in FIG. 8B, when the photosensitive film 300 is developed, the photosensitive film 300 has at least two thicknesses.

As illustrated in FIG. 8C, the metal material layer 170 and the semiconductor material layer 150 are etched by using the photosensitive film 300 as the mask to form the semiconductor pattern 154. The photosensitive film 300 is ashed and thus the portion of the photosensitive film 300 formed at a small thickness is removed.

As illustrated in FIG. 8D, the metal material layer 170 is etched by using the remaining photosensitive film 300 as the mask to form the source electrode 173 and the drain electrode 175.

The source electrode 173 and the drain electrode 175 are formed at both sides of the gate electrode 124, while being spaced apart from each other. The source electrode 173 and the drain electrode 175 are spaced apart from the gate electrode 124 to form the offset.

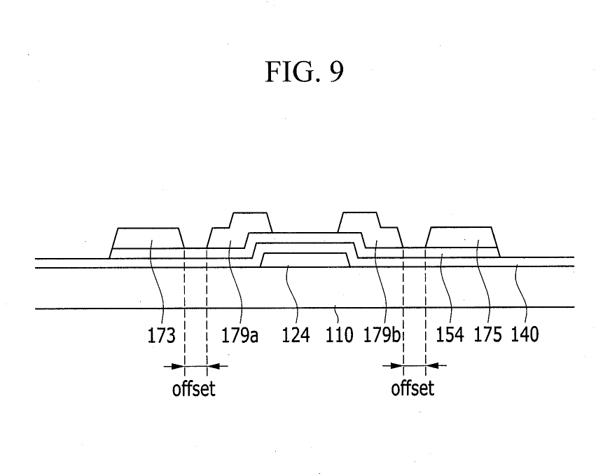

Next, the thin film transistor according to the exemplary embodiment of the disclosed technology will be described below with reference to FIG. 9.

The thin film transistor according to the exemplary embodiment of the disclosed technology illustrated in FIG. 9 is considerably the same as the thin film transistor according to the exemplary embodiment of the disclosed technology illustrated in FIG. 7 and therefore the description thereof will be omitted. The exemplary embodiment of the disclosed technology is different from the foregoing exemplary embodiments of the disclosed technology in that first and second floating electrodes are further formed and will be described below in more detail.

FIG. 9 is a cross-sectional view of the thin film transistor according to another exemplary embodiment of the disclosed technology.

The thin film transistor according to the exemplary embodiment of the disclosed technology includes the gate electrode 0, the gate insulating layer 140, and the semiconductor pattern 154. The gate electrode 124 is formed on the substrate 110. The gate insulating layer 140 is formed on the gate electrode 124. The semiconductor pattern 154 is made of the oxide semiconductor and formed on the gate insulating layer 140.

The source electrode 173 and the drain electrode 175 are formed on the semiconductor pattern 154. The source electrode 173 and the drain electrode 175 are spaced apart from each other. The source electrode 173 and the drain electrode 175 are spaced apart from the gate electrode 124. That is, the source electrode 173 and the drain electrode 175 are formed so as not to overlap the gate electrode 124.

A first floating electrode 179a and a second floating electrode 179b are formed on the semiconductor pattern 154. The first floating electrode 179a and the second floating electrode 179b are made of the same material as the source electrode 173 and the drain electrode 175 and are formed on the same layer as the source electrode 173 and the drain electrode 175. The first floating electrode 179a and the second floating electrode 179b are formed in a floated state. The first floating electrode 179a and the second floating electrode 179b are spaced apart from each other. The first floating electrode 179a and the second floating electrode 179b are formed between the source electrode 173 and the drain electrode 175 and are spaced apart from the source electrode 173 and the drain electrode 175. The first floating electrode 179a and the second floating electrode 179b partially overlap the gate electrode 124.

Further, the disclosed technology is not limited thereto, and the first floating electrode 179a and the second floating electrode 179b may also be spaced apart from the gate electrode 124. That is, the first floating electrode 179a and the second floating electrode 179b may not overlap the gate electrode 124.

The first floating electrode 179a is formed between the gate electrode 124 and the source electrode 173. The first floating electrode 179a overlaps one end of the gate electrode 124. The gate electrode 124 is adjacent to the source electrode 173. An offset is formed between the first floating electrode 179a and the source electrode 173 as much as the distance at which the first floating electrode 179a and the source electrode 173 are spaced apart from each other.

The second floating electrode 179b is formed between the gate electrode 124 and the drain electrode 175. The second floating electrode 179b overlaps the other end of the gate electrode 124. The gate electrode 124 is adjacent to the drain electrode 175. An offset is formed between the second floating electrode 179b and the drain electrode 175 as much as the distance at which the second floating electrode 179b and the drain electrode 175 are spaced apart from each other.

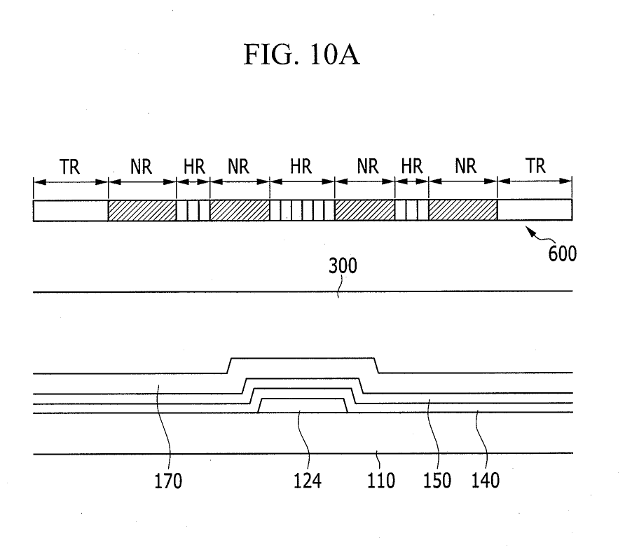

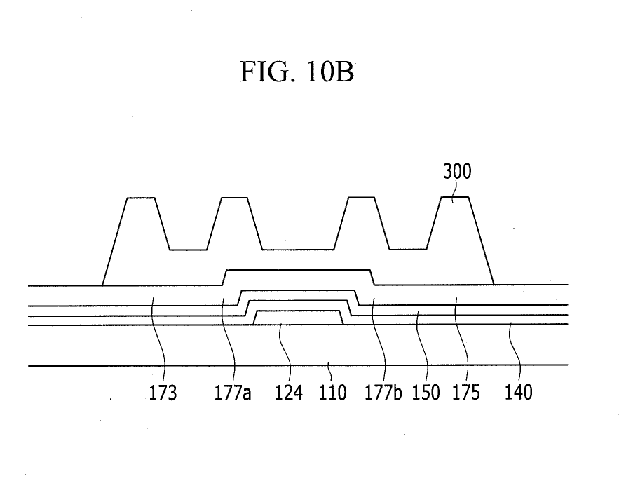

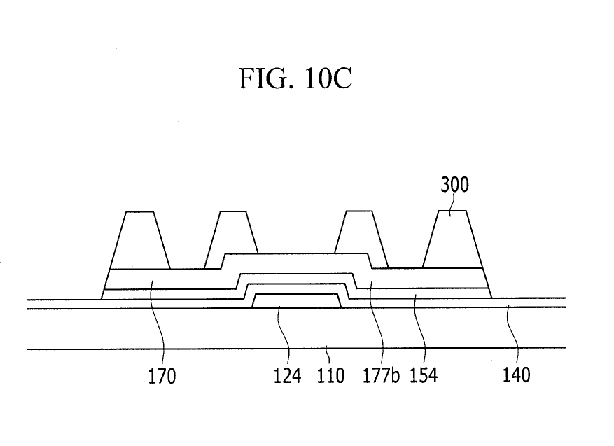

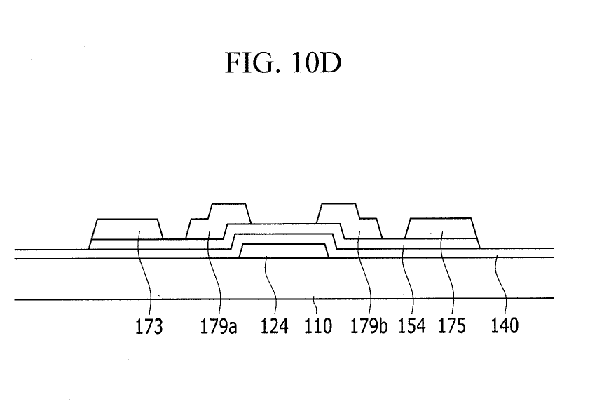

Next, a method for manufacturing a thin film transistor according to another exemplary embodiment of the disclosed technology will be described below with reference to FIGS. 10A to 10D.

FIGS. 10A to 10D are process cross-sectional views of a method for manufacturing a thin film transistor according to another exemplary embodiment of the disclosed technology.

As illustrated in FIG. 10A, the gate electrode 124 is formed on the substrate 110 and the gate insulating layer 140 is formed on the gate electrode 124. The semiconductor material layer 150 made of the oxide semiconductor material is formed on the gate insulating layer 140 and the metal material layer 170 is formed on the semiconductor material layer 150. The photosensitive film 300 is formed on the metal material layer 170 and the mask 600 is applied on the substrate 110 and undergoes the exposure process by being irradiated with light. The mask 600 includes the transmitting part TR, the non-transmitting part NR, and the half transmitting part HR.

As illustrated in FIG. 10B, when the photosensitive film 300 is developed, the photosensitive film 300 has at least two thicknesses.

As illustrated in FIG. 10C, the metal material layer 170 and the semiconductor material layer 150 are etched by using the photosensitive film 300 as the mask to form the semiconductor pattern 154. The photosensitive film 300 is ashed and thus the portion of the photosensitive film 300 formed at a small thickness is removed.

As illustrated in FIG. 10D, the metal material layer 170 is etched by using the remaining photosensitive film 300 as the mask to form the source electrode 173, the drain electrode 175, the first floating electrode 179a, and the second floating electrode 179b.

The source electrode 173 and the drain electrode 175 are formed at both sides of the gate electrode 124, while being spaced apart from each other. The first floating electrode 179a and the second floating electrode 179b are formed between the source electrode 173 and the drain electrode 175, while being spaced apart from each other. The first floating electrode 179a and the second floating electrode 179b are formed to be spaced apart from the source electrode 173 and the drain electrode 175. The first floating electrode 179a and the second floating electrode 179b may partially overlap or may be spaced apart from the gate electrode 124.

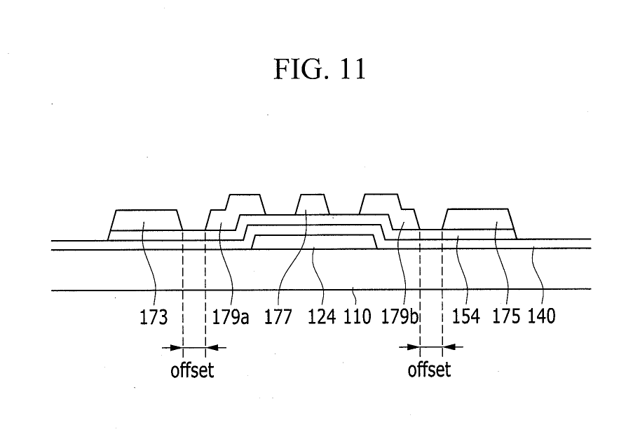

Next, the thin film transistor according to the exemplary embodiment of the disclosed technology will be described below with reference to FIG. 11.

The thin film transistor according to the exemplary embodiment of the disclosed technology illustrated in FIG. 11 is considerably the same as the thin film transistor according to the exemplary embodiment of the disclosed technology illustrated in FIG. 9 and therefore the description thereof will be omitted. The exemplary embodiment of the disclosed technology is different from the foregoing exemplary embodiments of the disclosed technology in that a floating gate electrode is further formed and will be described below in more detail.

FIG. 11 is a cross-sectional view of the thin film transistor according to another exemplary embodiment of the disclosed technology.

The thin film transistor according to the exemplary embodiment of the disclosed technology includes the gate electrode 124, the gate insulating layer 140, and the semiconductor pattern 154. The gate electrode 124 is formed on the substrate 110. The gate insulating layer 140 is formed on the gate electrode 124. The semiconductor pattern 154 is formed of the oxide semiconductor and is formed on the gate insulating layer 140.

The source electrode 173 and the drain electrode 175 are formed on the semiconductor pattern 154. The source electrode 173 and the drain electrode 175 are spaced apart from each other. The source electrode 173 and the drain electrode 175 are spaced apart from the gate electrode 124. That is, the source electrode 173 and the drain electrode 175 are formed so as not to overlap the gate electrode 124.

A first floating electrode 179a and a second floating electrode 179b are formed on the semiconductor pattern 154. The first floating electrode 179a and the second floating electrode 179b are made of the same material as the source electrode 173 and the drain electrode 175 and are formed on the same layer as the source electrode 173 and the drain electrode 175. The first floating electrode 179a and the second floating electrode 179b are formed in a floated state. The first floating electrode 179a and the second floating electrode 179b are spaced apart from each other. The first floating electrode 179a and the second floating electrode 179b are formed between the source electrode 173 and the drain electrode 175 and are spaced apart from the source electrode 173 and the drain electrode 175. The first floating electrode 179a and the second floating electrode 179b may partially overlap or may be spaced apart from the gate electrode 124.

The first floating electrode 179a is formed between the gate electrode 124 and the source electrode 173 and the second floating electrode 179b is formed between the gate electrode 124 and the drain electrode 175.

The floating gate electrode 177 is formed on the semiconductor pattern 154. The floating gate electrode 177 is formed in a floated state. The floating gate electrode 177 is formed to overlap the gate electrode 124 and is particularly formed to overlap a central portion of the gate electrode 124. The floating gate electrode 177 is formed between the first floating electrode 179a and the second floating electrode 179b and is spaced apart from the first floating electrode 179a and the second floating electrode 179b.

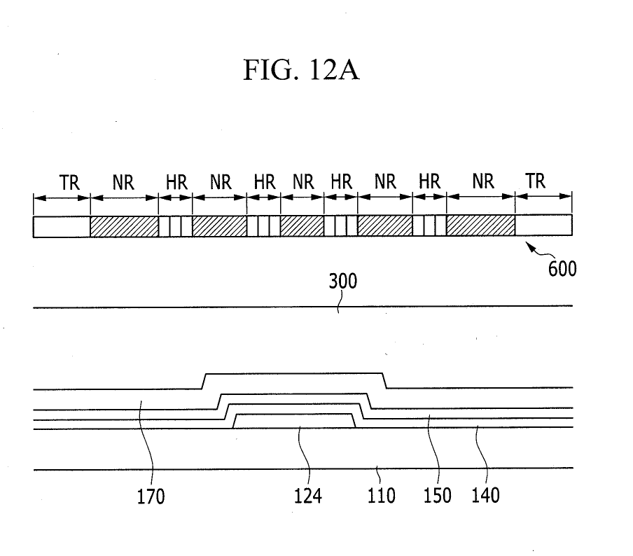

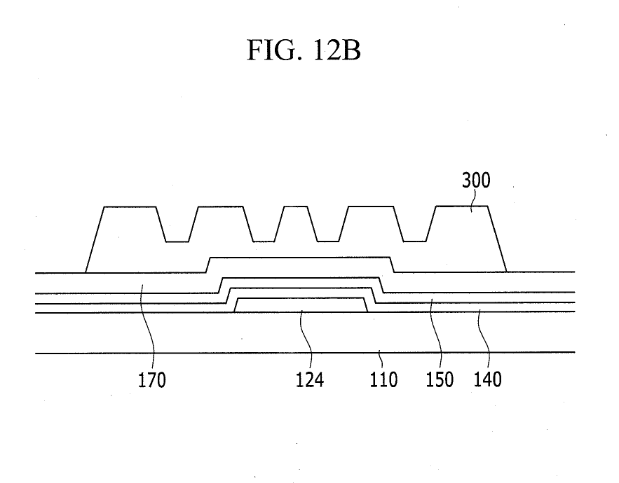

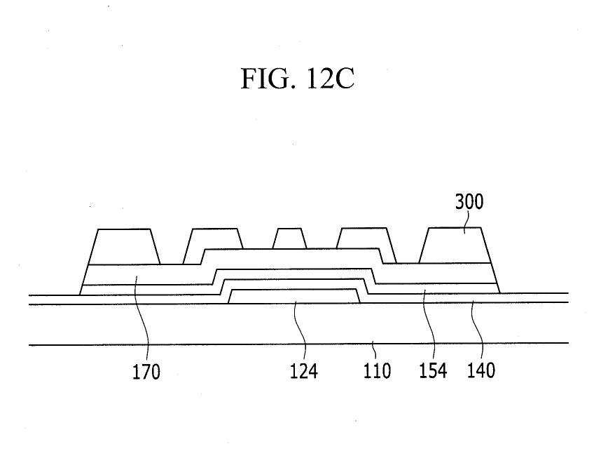

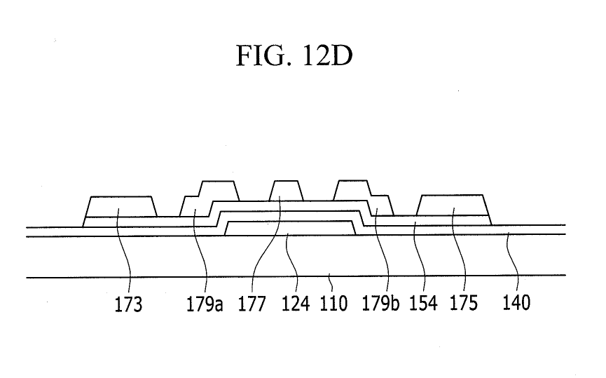

Next, a method for manufacturing a thin film transistor according to another exemplary embodiment of the disclosed technology will be described below with reference to FIGS. 12A and 12B.

FIGS. 12A to 12D are process cross-sectional views of a method for manufacturing a thin film transistor according to another exemplary embodiment of the disclosed technology.

As illustrated in FIG. 12A, the gate electrode 124 is formed on the substrate 110 and the gate insulating layer 140 is formed on the gate electrode 124. The semiconductor material layer 150 made of the oxide semiconductor material is formed on the gate insulating layer 140 and the metal material layer 170 is formed on the semiconductor material layer 150. The photosensitive film 300 is formed on the metal material layer 170 and the mask 600 is applied on the substrate 110 and undergoes the exposure process by being irradiated with light. The mask 600 includes the transmitting part TR, the non-transmitting part NR, and the half transmitting part HR.

As illustrated in FIG. 12B, when the photosensitive film 300 is developed, the photosensitive film 300 has at least two thicknesses.

As illustrated in FIG. 12C, the metal material layer 170 and the semiconductor material layer 150 are etched by using the photosensitive film 300 as the mask to form the semiconductor pattern 154. The photosensitive film 300 is ashed and thus the portion of the photosensitive film 300 formed at a small thickness is removed.

As illustrated in FIG. 12D, the metal material layer 170 is etched by using the remaining photosensitive film 300 as the mask to form the source electrode 173, the drain electrode 175, the first floating electrode 179a, the second floating electrode 179b, and the floating gate electrode 177.

The source electrode 173 and the drain electrode 175 are formed at both sides of the gate electrode 124, while being spaced apart from each other. The first floating electrode 179a and the second floating electrode 179b are formed between the source electrode 173 and the drain electrode 175, while being spaced apart from each other. The first floating electrode 179a and the second floating electrode 179b are spaced apart from the source electrode 173 and the drain electrode 175 to form the offset. The first floating electrode 179a and the second floating electrode 179b may partially overlap or may be spaced apart from the gate electrode 124.

The floating gate electrode 177 is formed between the first floating electrode 179a and the second floating electrode 179b. The floating gate electrode 177 is formed to be spaced apart from the first floating electrode 179a and the second floating electrode 179b. The floating gate electrode 177 is formed to overlap the gate electrode 124 and is particularly formed to overlap the central portion or the gate electrode 124.

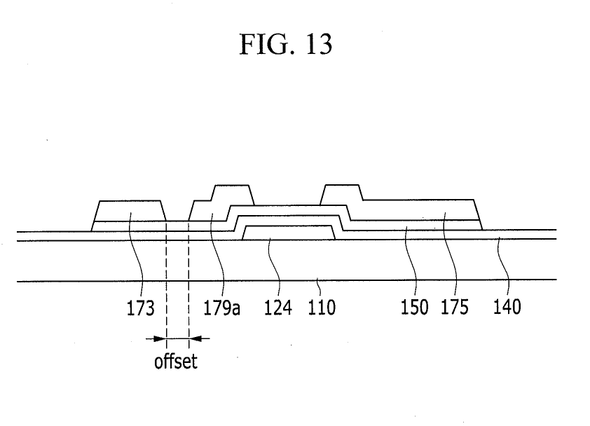

Next, the thin film transistor according to the exemplary embodiment of the disclosed technology will be described below with reference to FIG. 13.

The thin film transistor according to the exemplary embodiment of the disclosed technology illustrated in FIG. 13 is considerably the same as the thin film transistor according to the exemplary embodiment of the disclosed technology illustrated in FIG. 9 and therefore the description thereof will be omitted. The exemplary embodiment of the disclosed technology is different from the foregoing exemplary embodiments of the disclosed technology in that the drain electrode is formed to overlap the gate electrode and will be described below in more detail.

FIG. 13 is a cross-sectional view of the thin film transistor according to the exemplary embodiment of the disclosed technology.

The thin film transistor according to the exemplary embodiment of the disclosed technology includes the gate electrode 124, the gate insulating layer 140, and the semiconductor pattern 154. The gate electrode 124 is formed on the substrate 110. The gate insulating layer 140 is formed on the gate electrode 124. The semiconductor pattern 154 is formed of the oxide semiconductor and is formed on the gate insulating layer 140.

The source electrode 173 and the drain electrode 175 are formed on the semiconductor pattern 154. The source electrode 173 and the drain electrode 175 are spaced apart from each other. The source electrode 173 is spaced apart from the gate electrode 124. That is, the source electrode 173 is formed so as not to overlap the gate electrode 124. The drain electrode 175 partially overlaps the gate electrode 124.

The first floating electrode 179a is formed on the semiconductor pattern 154. The first floating electrode 179a is formed of the same material as the source electrode 173 and the drain electrode 175 and is formed on the same layer as the source electrode 173 and the drain electrode 175. The first floating electrode 179a is formed in a floated state. The first floating electrode 179a is formed between the source electrode 173 and the drain electrode 175 and is spaced apart from the source electrode 173 and the drain electrode 175.

The first floating electrode 179a may partially overlap the gate electrode 124 or may be spaced apart from the gate electrode 124. The first floating electrode 179a is formed between the gate electrode 124 and the source electrode 173. The first floating electrode 179a may overlap one end of the gate electrode 124 which is adjacent to the source electrode 173. The offset is formed between the first floating electrode 179a and the source electrode 173 as much as the distance at which the first floating electrode 179a and the source electrode 173 are spaced apart from each other.

The disclosed technology describes that the drain electrode 175 partially overlaps the gate electrode 124 and the first floating electrode 179a is formed between the gate electrode 124 and the source electrode 173, but is not limited thereto. The source electrode 173 may partially overlap the gate electrode 124 and the first floating electrode 179a may be formed between the gate electrode 124 and the drain electrode 175. In this case, the drain electrode 175 may not overlap the gate electrode 124 and the first floating electrode 179a may overlap one end of the gate electrode 124 which is adjacent to the drain electrode 175. Further, the first floating electrode 179a may not overlap the gate electrode 124, but spaced apart from the gate electrode 124,

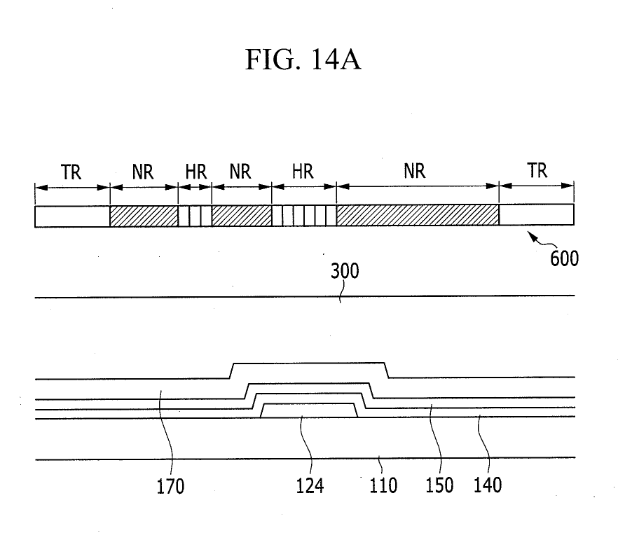

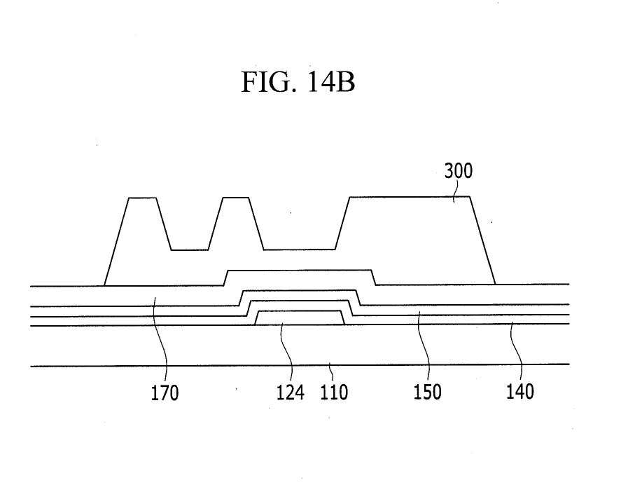

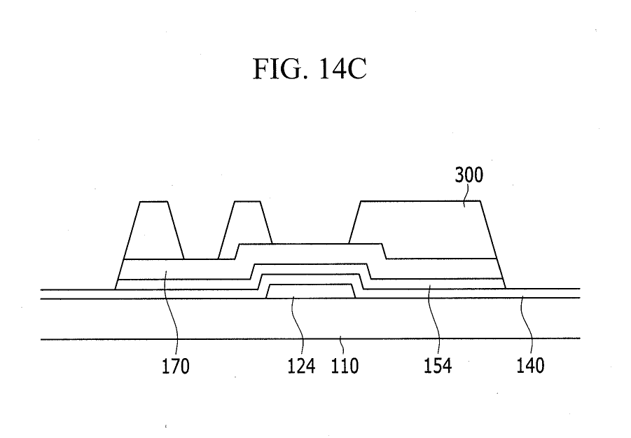

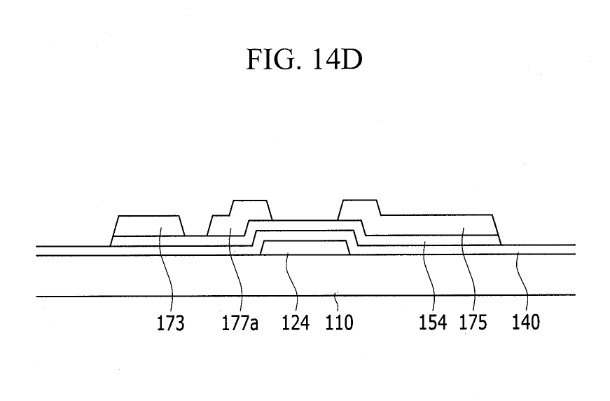

Next, a method for manufacturing a thin film transistor according to another exemplary embodiment of the disclosed technology will be described below with reference to FIGS. 14A to 14D.

FIGS. 14A to 14D are process cross-sectional views of a method for manufacturing a thin film transistor according to another exemplary embodiment of the disclosed technology.

As illustrated in FIG. 14A, the gate electrode 124 is formed on the substrate 110 and the gate insulating layer 140 is formed on the gate electrode 124. The semiconductor material layer 150 formed of the oxide semiconductor material is formed on the gate insulating layer 140 and the metal material layer 170 is formed on the semiconductor material layer 150. The photosensitive film 300 is formed on the metal material layer 170 and the mask 600 is applied on the substrate 110 and undergoes the exposure process by being irradiated with light. The mask 600 includes the transmitting part TR, the non-transmitting part NR, and the half transmitting part HR.

As illustrated in FIG. 14B, when the photosensitive film 300 is developed, the photosensitive film 300 has at least two thicknesses.

As illustrated in FIG. 14C, the metal material layer 170 and the semiconductor material layer 150 are etched by using the photosensitive film 300 as the mask to form the semiconductor pattern 154. The photosensitive film 300 is ashed and thus the portion of the photosensitive film 300 formed at a small thickness is removed.

As illustrated in FIG. 14D, the metal material layer 170 is etched by using the remaining photosensitive film 300 as the mask to form the source electrode 173, the drain electrode 175, and the first floating electrode 179a.

The source electrode 173 and the drain electrode 175 are formed at both sides of the gate electrode 124, while being spaced apart from each other. The source electrode 173 is spaced apart from the gate electrode 124 and the drain electrode 175 partially overlaps the gate electrode 124.

The first floating electrode 179a is formed between the source electrode 173 and the drain electrode 175. The first floating electrode 179a is formed to be spaced apart from the source electrode 173 and the drain electrode 175. The first floating electrode 179a may partially overlap the gate electrode 124 or may be spaced apart from the gate electrode 124.

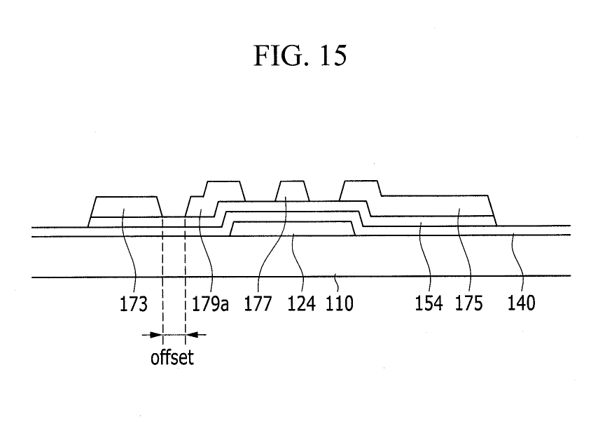

Next, the thin film transistor according to another exemplary embodiment of the disclosed technology will be described below with reference to FIG. 15.

The thin film transistor according to the exemplary embodiment of the disclosed technology illustrated in FIG. 15 is considerably the same as the thin film transistor according to the embodiment of the disclosed technology illustrated in FIG. 13 and therefore the description thereof will be omitted. The exemplary embodiment of the disclosed technology is different from the foregoing exemplary embodiments of the disclosed technology in that a floating gate electrode is further formed and will be described below in more detail.

FIG. 15 is a cross-sectional view of the thin film transistor according to another exemplary embodiment of the disclosed technology.

The thin film transistor according to the exemplary embodiment of the disclosed technology includes the gate electrode 124, the gate insulating layer 140, and the semiconductor pattern 154. The gate electrode 124 is formed on the substrate 110. The gate insulating layer 140 is formed on the gate electrode 124. The semiconductor pattern 154 is formed of the oxide semiconductor and formed on the gate insulating layer 140.

The source electrode 173 and the drain electrode 175 are formed on the semiconductor pattern 154. The source electrode 173 and the drain electrode 175 are spaced apart from each other. The source electrode 173 is spaced apart from the gate electrode 124. That is, the source electrode 173 is formed so as not to overlap the gate electrode 124. The drain electrode 175 partially overlaps the gate electrode 124.

The first floating electrode 179a is formed on the semiconductor pattern 154. The first floating electrode 179a is formed of the same material as the source electrode 173 and the drain electrode 175 and is formed on the same layer as the source electrode 173 and the drain electrode 175. The first floating electrode 179a is formed in a floated state. The first floating electrode 179a is formed between the source electrode 173 and the drain electrode 175 and is spaced apart from the source electrode 173 and the drain electrode 175. The first floating electrode 179a may partially overlap the gate electrode or may be spaced apart from the gate electrode.

The floating gate electrode 177 is formed on the semiconductor pattern 154. The floating gate electrode 177 is formed in a floated state. The floating gate electrode 177 is formed to overlap the gate electrode 124 and is particularly formed to overlap a central portion of the gate electrode 124. The floating gate electrode 177 is formed between the first floating electrode 179a and the drain electrode 175 and is spaced apart from the first floating electrode 179a and drain electrode 175.

The disclosed technology describes that the drain electrode 175 partially overlaps the gate electrode 124 and the first floating electrode 179a is formed between the gate electrode 124 and the source electrode 173, but is not limited thereto. The source electrode 173 may partially overlap the gate electrode 124 and the first floating electrode 179a may be formed between the gate electrode 124 and the drain electrode 175. In this case, the drain electrode 175 may not overlap the gate electrode 124 and the first floating electrode 179a may overlap one end of the gate electrode 124 which is adjacent to the drain electrode 175. Further, the first floating electrode 179a may not overlap the gate electrode 124, but spaced apart from the gate electrode 124,

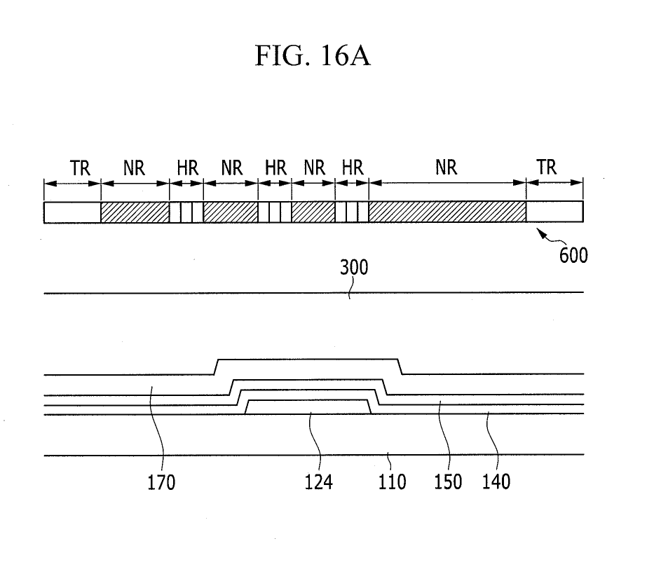

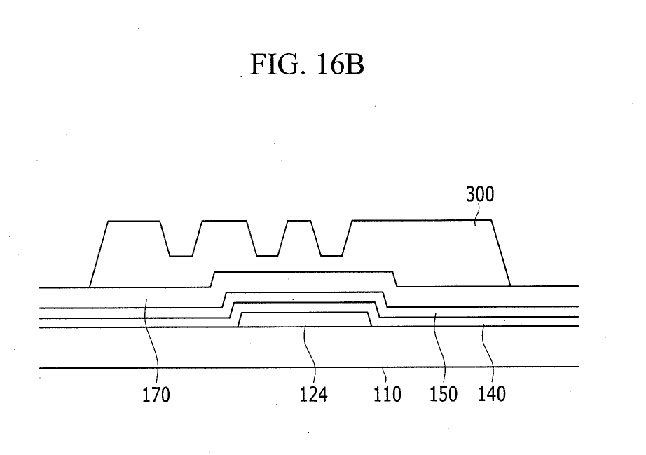

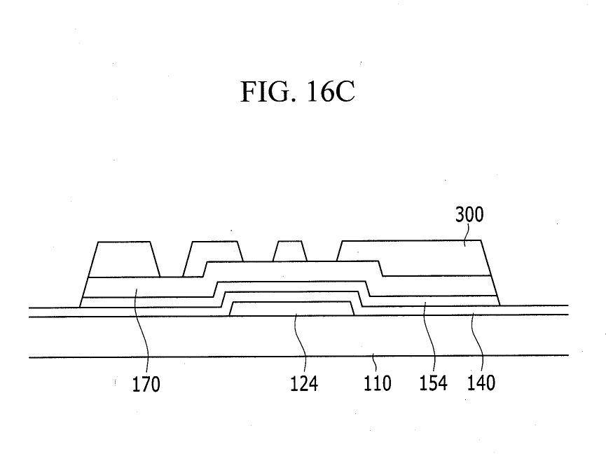

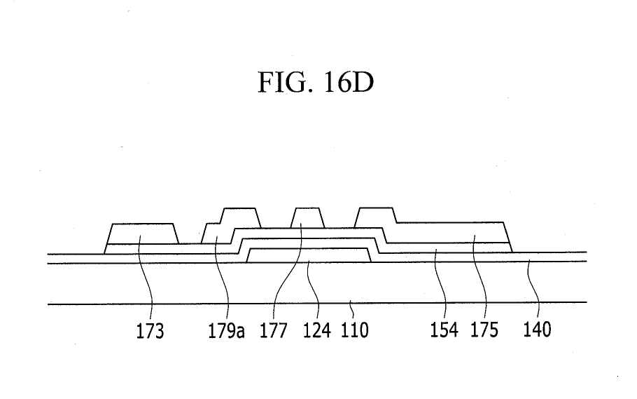

Next, a method for manufacturing a thin film transistor according to another exemplary embodiment of the disclosed technology will be described below with reference to FIGS. 16A to 16D.

FIGS. 16A to 16D are process cross-sectional views of a method for manufacturing a thin film transistor according to another exemplary embodiment of the disclosed technology.

As illustrated in FIG. 16A, the gate electrode 124 is formed on the substrate 110 and the gate insulating layer 140 is formed on the gate electrode 124. The semiconductor material layer 150 formed of the oxide semiconductor material is formed on the gate insulating layer 140 and the metal material layer 170 is formed on the semiconductor material layer 150. The photosensitive film 300 is formed on the metal material layer 170 and the mask 600 is applied on the substrate 110 and undergoes the exposure process by being irradiated with light. The mask 600 includes the transmitting part TR, the non-transmitting part NR, and the half transmitting part HR.

As illustrated in FIG. 16B, when the photosensitive film 300 is developed, the photosensitive film 300 has at least two thicknesses.

As illustrated in FIG. 16C, the metal material layer 170 and the semiconductor material layer 150 are etched by using the photosensitive film 300 as the mask to form the semiconductor pattern 154. The photosensitive film 300 is ashed and thus the portion of the photosensitive film 300 formed at a small thickness is removed.

As illustrated in FIG. 16D, the metal material layer 170 is etched by using the remaining photosensitive film 300 as the mask to form the source electrode 173, the drain electrode 175, the first floating electrode 179a, and the floating gate electrode 177.

The source electrode 173 and the drain electrode 175 are formed at both sides of the gate electrode 124, while being spaced apart from each other. The source electrode 173 is spaced apart from the gate electrode 124. The drain electrode 175 partially overlaps the gate electrode 124. The source electrode 173 does not overlap the gate electrode 124.

The first floating electrode 179a is formed between the source electrode 173 and the drain electrode 175. The first floating electrode 179a is formed to be spaced apart from the source electrode 173 and the drain electrode 175. The first floating electrode 179a may partially overlap the gate electrode 124 or may be spaced apart from the gate electrode 124.

The floating gate electrode 177 is formed to overlap the gate electrode 124 and is particularly formed to overlap the central portion of the gate electrode 124.

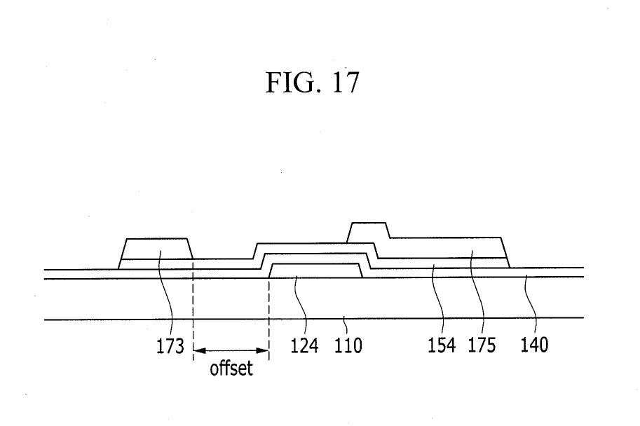

Next, the thin film transistor according to another exemplary embodiment of the disclosed technology will be described below with reference to FIG. 17.

The thin film transistor according to the exemplary embodiment of the disclosed technology illustrated in FIG. 17 is considerably the same as the thin film transistor according to the embodiment of the disclosed technology illustrated in FIG. 13 and therefore the description thereof will be omitted. The exemplary embodiment of the disclosed technology is different from the foregoing exemplary embodiments of the disclosed technology in that the first floating electrode is omitted and will be described below in more detail.

FIG. 17 is across-sectional view of the thin film transistor according to the exemplary embodiment of the disclosed technology.

The thin film transistor according to the exemplary embodiment of the disclosed technology includes the gate electrode 124, the gate insulating layer 140, and the semiconductor pattern 154. The gate electrode 124 is formed on the substrate 110. The gate insulating layer 140 is formed on the gate electrode 124. The semiconductor pattern 154 is formed of the oxide semiconductor and formed on the gate insulating layer 140.

The source electrode 173 and the drain electrode 175 are formed on the semiconductor pattern 154. The source electrode 173 and the drain electrode 175 are spaced apart from each other. The source electrode 173 is spaced apart from the gate electrode 124. That is, the source electrode 173 is formed so as not to overlap the gate electrode 124. The offset is formed between the source electrode 173 and the gate electrode 124. The offset is the same as the distance at which the source electrode 173 and the gate electrode 124 are spaced apart from each other. The drain electrode 175 partially overlaps the gate electrode 124.

The disclosed technology describes that the drain electrode 175 partially overlaps the gate electrode 124 and the source electrode 173 is spaced apart from the gate electrode 124, but is not limited thereto. The source electrode 173 may partially overlap the gate electrode 124. The drain electrode 175 may be spaced apart from the gate electrode 124. The drain electrode 175 does not overlap the gate electrode 124.

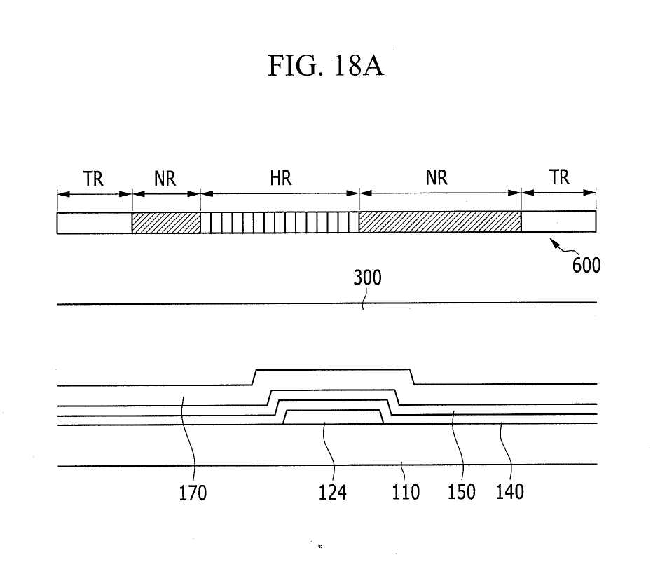

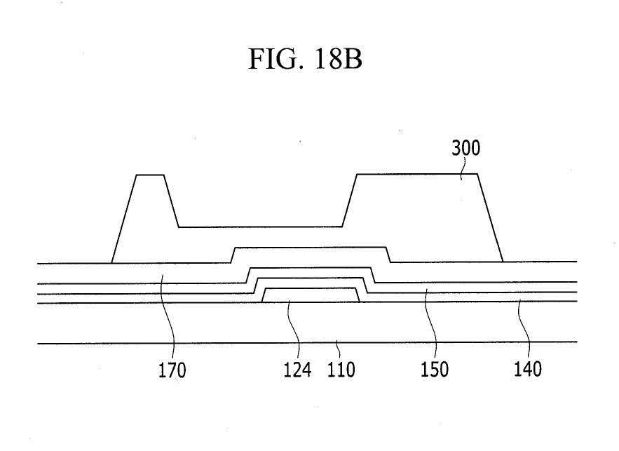

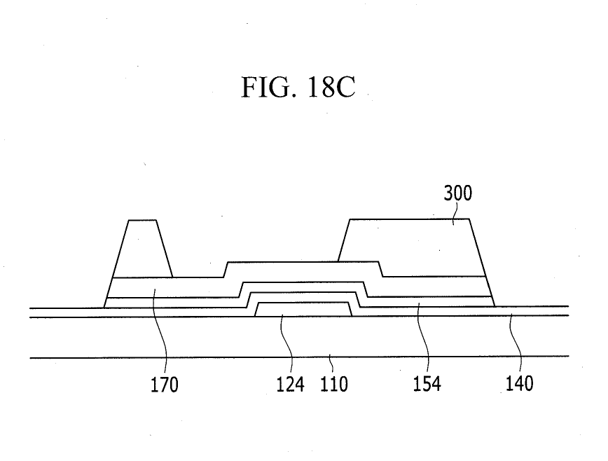

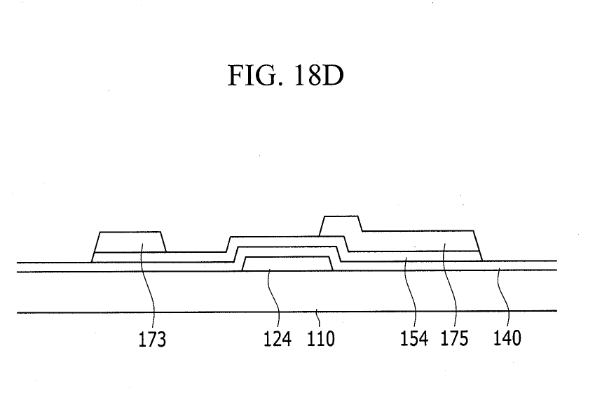

Next, a method for manufacturing a thin film transistor according to another exemplary embodiment of the disclosed technology will be described below with reference to FIGS. 18A to 18D.

FIGS. 18A to 18D are process cross-sectional views of a method for manufacturing a thin film transistor according to another exemplary embodiment of the disclosed technology.

As illustrated in FIG. 18A, the gate electrode 124 is formed on the substrate 110 and the gate insulating layer 140 is formed on the gate electrode 124. The semiconductor material layer 150 formed of the oxide semiconductor material is formed on the gate insulating layer 140. The metal material layer 170 is formed on the semiconductor material layer 150. The photosensitive film 300 is formed on the metal material layer 170. The mask 600 is applied on the substrate 110 and undergoes the exposure process by being irradiated with light. The mask 600 includes the transmitting part TR, the non-transmitting part NR, and the half transmitting part HR.

As illustrated in FIG. 18B, when the photosensitive film 300 is developed, the photosensitive film 300 has at least two thicknesses.

As illustrated in FIG. 18C, the metal material layer 170 and the semiconductor material layer 150 are etched by using the photosensitive film 300 as the mask to form the semiconductor pattern 154. The photosensitive film 300 is ashed and thus the portion of the photosensitive film 300 formed at a small thickness is removed.

As illustrated in FIG. 18D, the metal material layer 170 is etched by using the remaining photosensitive film 300 as the mask to form the source electrode 173 and the drain electrode 175.

The source electrode 173 and the drain electrode 175 are formed at both sides of the gate electrode 124, while being spaced apart from each other. The source electrode 173 is spaced apart from the gate electrode 124. The drain electrode 175 partially overlaps the gate electrode 124. The source electrode 173 does not overlap the gate electrode 124.

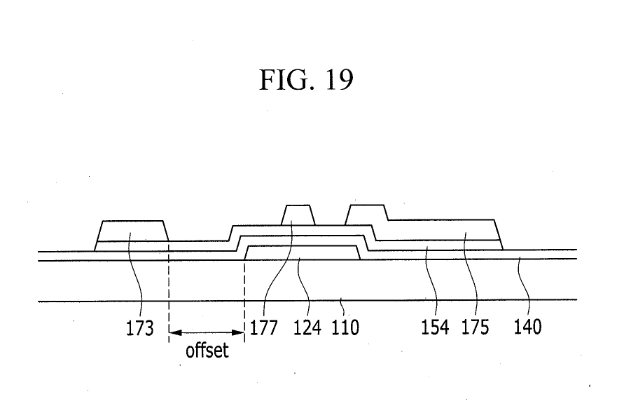

Next, the thin film transistor according to another exemplary embodiment of the disclosed technology will be described below with reference to FIG. 19.

The thin film transistor according to the exemplary embodiment of the disclosed technology illustrated in FIG. 19 is considerably the same as the thin film transistor according to the exemplary embodiment of the disclosed technology illustrated in FIG. 17 and therefore the description thereof will be omitted. The exemplary embodiment of the disclosed technology is different from the foregoing exemplary embodiments of the disclosed technology in that a floating gate electrode is further formed and will be described below in more detail.

FIG. 19 is a cross-sectional view of the thin film transistor according to another exemplary embodiment of the disclosed technology.

The thin film transistor according to the exemplary embodiment of the disclosed technology includes the gate electrode 124, the gate insulating layer 140, and the semiconductor pattern 154. The gate electrode 124 is formed on the substrate 110. The gate insulating layer 140 is formed on the gate electrode 124. The semiconductor pattern 154 is formed of the oxide semiconductor and formed on the gate insulating layer 140.

The source electrode 173 and the drain electrode 175 are formed on the semiconductor pattern 154. The source electrode 173 and the drain electrode 175 are spaced apart from each other. The source electrode 173 is spaced apart from the gate electrode 124. That is, the source electrode 173 is formed so as not to overlap the gate electrode 124. The offset is formed between the source electrode 173 and the gate electrode 124. The offset is the same as the distance at which the source electrode 173 and the gate electrode 124 are spaced apart from each other. The drain electrode 175 partially overlaps the gate electrode 124.

The floating gate electrode 177 is formed on the semiconductor pattern 154. The floating gate electrode 177 is formed in a floated state. The floating gate electrode 177 is formed to overlap the gate electrode 124. The floating gate electrode 177 is particularly formed to overlap a central portion of the gate electrode 124. The floating gate electrode 177 is formed between the source electrode 173 and the drain electrode 175. The floating gate electrode 177 is spaced apart from the source electrode 173 and the drain electrode 175. The floating gate electrode 177 does not overlap the source electrode 173 and the drain electrode 175.

The disclosed technology describes that the drain electrode 175 partially overlaps the gate electrode 124 and the source electrode 173 is spaced apart from the gate electrode 124, but is not limited thereto. The source electrode 173 may partially overlap the gate electrode 124. The drain electrode 175 may be spaced apart from the gate electrode 124. The drain electrode 175 does not overlap the gate electrode 124.

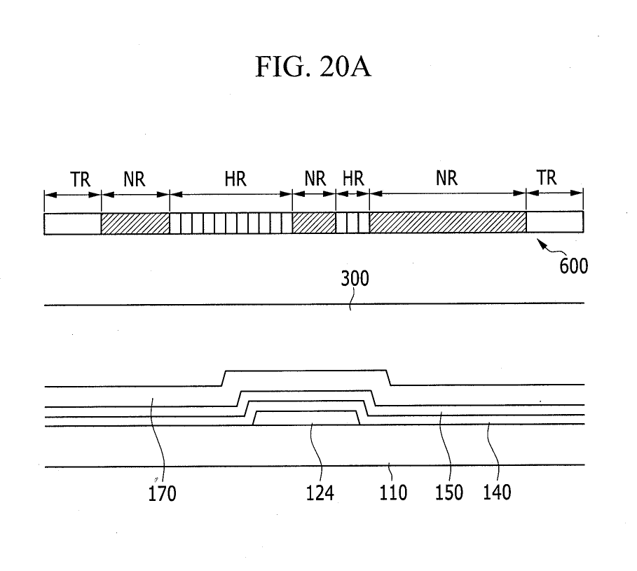

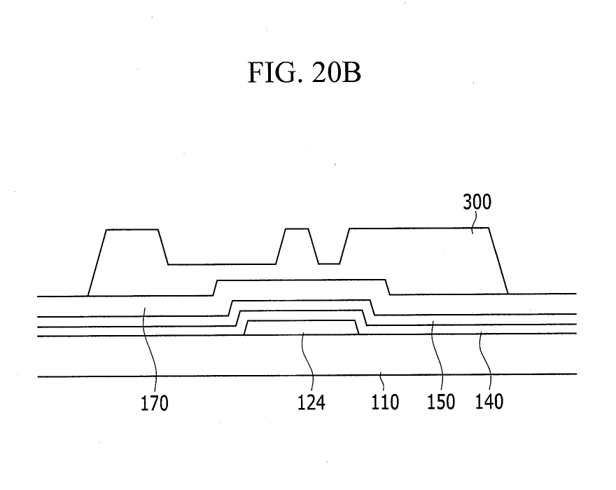

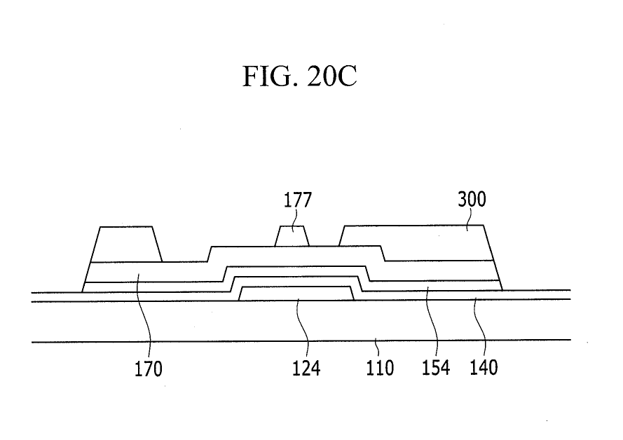

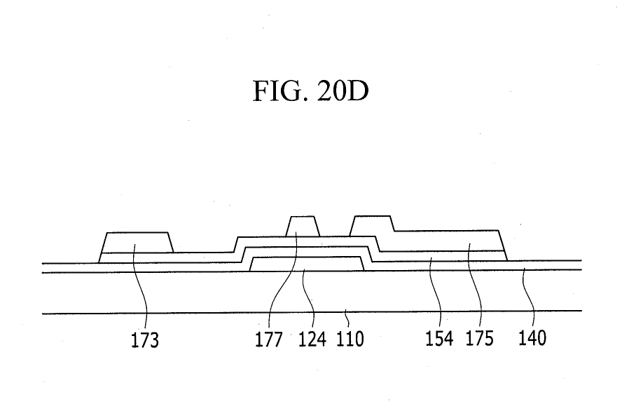

Next, a method for manufacturing a thin film transistor according to the exemplary embodiment of the disclosed technology will be described below with reference to FIGS. 20A to 20D.

FIGS. 20A to 20D are process cross-sectional views of a method for manufacturing a thin film transistor according to another exemplary embodiment of the disclosed technology.

As illustrated in FIG. 20A, the gate electrode 124 is formed on the substrate 110. The gate insulating layer 140 is formed on the gate electrode 124. The semiconductor material layer 150 is formed of the oxide semiconductor material. The semiconductor material layer 150 is formed on the gate insulating layer 140. The metal material layer 170 is formed on the semiconductor material layer 150. The photosensitive film 300 is formed on the metal material layer 170. The mask 600 is applied on the substrate 110 and undergoes the exposure process by being irradiated with light. The mask 600 includes the transmitting part TR, the non-transmitting part NR, and the half transmitting part HR.

As illustrated in FIG. 20B, when the photosensitive film 300 is developed, the photosensitive film 300 has at least two thicknesses.

As illustrated in FIG. 20C, the metal material layer 170 and the semiconductor material layer 150 are etched by using the photosensitive film 300 as the mask to form the semiconductor pattern 154. The photosensitive film 300 is ashed and thus the portion of the photosensitive film 300 formed at a small thickness is removed.

As illustrated in FIG. 20D, the metal material layer 170 is etched by using the remaining photosensitive film 300 as the mask to form the source electrode 173, the drain electrode 175, and the floating gate electrode 177.

The source electrode 173 and the drain electrode 175 are formed at both sides of the gate electrode 124, while being spaced apart from each other. The source electrode 173 is spaced apart from the gate electrode 124 and the drain electrode 175 partially overlaps the gate electrode 124.

The floating gate electrode 177 is formed to overlap the gate electrode 124 and is particularly formed to overlap the central portion of the gate electrode 124.

While this inventive technology has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A display device, comprising:
a gate driver; and
at least one thin film transistor including:
a gate electrode;
a semiconductor pattern formed on the gate electrode and formed of an oxide semiconductor material; and
a source electrode and a drain electrode formed on the semiconductor pattern, wherein the source and drain electrodes are spaced apart from each other, wherein at least one of the source electrode or the drain electrode does not overlap the gate electrode.

2. The display device of claim 1, wherein the gate driver includes at least n ordered stages connected to each other in a cascade form, wherein n is a natural number, and wherein the n-th stage includes:
a pull-up unit configured to output a high voltage of a clock signal as a high voltage of an n-th gate signal in response to a signal of a first contact;
a buffer unit including a control terminal and an input terminal which are connected to a first input terminal and an output terminal, the first terminal configured to receive an n−1-th carry signal, and the output terminal connected to the first contact;
a pull-down unit configured to lower the high voltage of the n-th gate signal to a first low voltage in response to an n+1-th carry signal;
a discharging unit configured to discharge the voltage of the first contact as a second low voltage having a level lower than the first low voltage in response to the n+1-th carry signal;
a carry unit configured to output the high voltage of the clock signal as an n-th carry signal in response to the signal of the first contact;
an inverter unit configured to output a signal synchronized with the clock signal to a second contact for a period other than a period in which the n-th carry signal is output; and
a first contact holding unit configured to hold the voltage of the first contact, wherein the first contact is configured to be discharged as the second low voltage at the second low voltage in response to the signal of the second contact, and wherein at least one of the buffer unit or the first contact holding unit includes the thin film transistor.

3. The display device of claim 2, further comprising a first floating electrode formed on the semiconductor pattern,
wherein the first floating electrode partially overlaps or is spaced apart from the gate electrode, and
wherein the first floating electrode is spaced apart from the source electrode and the drain electrode.

4. The display device of claim 3, wherein the source electrode is spaced apart from the gate electrode, and
wherein the first floating electrode is formed between the gate electrode and the source electrode.

5. The display device of claim 4, further comprising a second floating electrode formed on the semiconductor pattern,
wherein the drain electrode is spaced apart from the gate electrode,
wherein the second floating electrode partially overlaps or is spaced apart from the gate electrode,
wherein the second floating electrode is spaced apart from the source electrode and the drain electrode, and
wherein the second floating electrode is formed between the gate electrode and the drain electrode.

6. The display device of claim 4, wherein the drain electrode overlaps the gate electrode.

7. The display device of claim 1, further comprising a first floating electrode formed on the semiconductor pattern,
wherein the first floating electrode partially overlaps or is spaced apart from the gate electrode, and
wherein the first floating electrode is spaced apart from the source electrode and the drain electrode.

8. The display device of claim 7, wherein the source electrode is spaced apart from the gate electrode, and wherein the first floating electrode is formed between the gate electrode and the source electrode.

9. The display device of claim 8, further comprising a second floating electrode formed on the semiconductor pattern,
wherein the drain electrode is spaced apart from the gate electrode,
wherein the second floating electrode partially overlaps or is spaced apart from the gate electrode,
wherein the second floating electrode is spaced apart from the source electrode and the drain electrode, and
wherein the second floating electrode is formed between the gate electrode and the drain electrode.

10. The display device of claim 8, wherein the drain electrode overlaps the gate electrode.

11. The display device of claim 1, wherein the source electrode is spaced apart from the gate electrode, and wherein the drain electrode overlaps the gate electrode.

12. The display device of claim 1, further comprising a second floating electrode formed on the semiconductor pattern,
wherein the second floating electrode partially overlaps or is spaced apart from the gate electrode, and
wherein the second floating electrode does not overlap the source electrode and the drain electrode.

13. The display device of claim 12, wherein the drain electrode is spaced apart from the gate electrode, and wherein the second floating electrode is formed between the gate electrode and the drain electrode.

14. The display device of claim 13, wherein the source electrode overlaps the gate electrode.

15. The display device of claim 1, wherein the drain electrode is spaced apart from the gate electrode, and wherein the source electrode overlaps the gate electrode.

16. The display device of claim 1, further comprising a floating gate electrode formed on the semiconductor pattern.

17. The display device of claim 16, further comprising a first floating electrode formed on the semiconductor pattern,
wherein the first floating electrode partially overlaps or is spaced apart from the gate electrode, and
wherein is spaced apart from the source electrode and the drain electrode.

18. The display device of claim 17, wherein the source electrode is spaced apart from the gate electrode, and wherein the first floating electrode is formed between the gate electrode and the source electrode.

19. The display device of claim 18, further comprising a second floating electrode formed on the semiconductor pattern,
wherein the drain electrode is spaced apart from the gate electrode,
wherein the second floating electrode partially overlaps or is spaced apart from the gate electrode,
wherein the second floating electrode is spaced apart from the source electrode and the drain electrode, and
wherein is formed between the gate electrode and the drain electrode.

20. The display device of claim 18, wherein the drain electrode overlaps the gate electrode.
